(19) United States
(12) Patent Application Publication
(10) Pub. No.: US 2025/0336673 A1
(43) Pub. Date: Oct. 30, 2025

(54) METHODS FOR SUBSTRATE PATTERNING PROCESS

(71) Applicant: Tokyo Electron Limited, Tokyo (JP)

(72) Inventors: Phillip D. Hustad, Schenectady, NY (US); Jordan B. Greenough, Schenectady, NY (US); Max J. Klemes, Schenectady, NY (US)

(21) Appl. No.: 19/097,641

(22) Filed: Apr. 1, 2025

Related U.S. Application Data
(60) Provisional application No. 63/638,765, filed on Apr. 25, 2024.

(51) Int. Cl. H01L 21/027; H01L 21/311; H01L 21/3213

(52) U.S. Cl. CPC H01L 21/0273; H01L 21/31144; H01L 21/32139

(57) ABSTRACT

A method is provided for processing a substrate. The method includes providing a substrate having a first patterned resist layer disposed over a layer to-be-etched, where the first patterned resist layer includes solubility shifting agent. A second resist layer is disposed over the first patterned resist layer. The solubility shifting agent diffuses into the second resist layer to form solubility shifted regions in the second resist layer. The solubility shifted regions are removed using a dry development process to form a second patterned resist layer. The layer to-be-etched is etched using the first and the second patterned resist layers as a combined etch mask.

### CROSS-REFERENCE TO RELATED APPLICATIONS

This application claims the benefit of U.S. Provisional Application No. 63/638,765, filed on Apr. 25, 2024, which application is hereby incorporated herein by reference.

### TECHNICAL FIELD

The present invention relates generally to a method for semiconductor device manufacturing, and, in particular embodiments, to a method for patterning a substrate.

### BACKGROUND

Semiconductor device fabrication involves multiple processing steps including material deposition, pattern formation, and pattern transfer. Material layers are formed on a substrate using various deposition techniques such as spin coating and vapor deposition. Pattern formation typically utilizes a photosensitive material, known as photoresist, which is exposed to actinic radiation through a patterned mask. The radiation sources commonly include KrF excimer lasers operating at 248 nm, ArF excimer lasers at 193 nm, or extreme ultraviolet (EUV) tools at 13.5 nm wavelength.

After exposure, the photoresist is developed to create a relief pattern that functions as an etch mask during subsequent pattern transfer steps. The relief pattern protects underlying portions of the substrate during etching processes while allowing other areas to be selectively removed. As semiconductor device dimensions continue to shrink, forming closely spaced line cuts in the substrate becomes increasingly challenging using conventional single-exposure lithography techniques.

Pattern transfer often requires intermediate layers between the photoresist and the substrate, such as hard mask layers or bottom antireflective coating (BARC) layers. The pattern is first transferred into these intermediate layers before final transfer into the substrate. This multi-layer approach helps maintain pattern fidelity but increases process complexity and manufacturing costs.

### SUMMARY

In accordance with one aspect of the present invention, a method is provided for processing a substrate. The method includes providing a substrate comprising a first patterned resist layer disposed over a layer to-be-etched, wherein the first patterned resist layer comprises solubility shifting agent. The method further includes disposing a second resist layer over the first patterned resist layer, and diffusing the solubility shifting agent into the second resist layer to form solubility shifted regions in the second resist layer. The method additionally includes removing the solubility shifted regions using a dry development process to form a second patterned resist layer, and etching the layer to-be-etched using the first and the second patterned resist layers as a combined etch mask.

In accordance with another aspect of the present invention, a method is provided for patterning a substrate. The method includes providing a substrate comprising a first patterned resist layer, and disposing a coating layer comprising solubility shifting agent over the first patterned resist layer, wherein the solubility shifting agent diffuses into the first patterned resist layer. The method further includes disposing a second resist layer over the first patterned resist layer, and activating the solubility shifting agent to diffuse the solubility shifting agent in the first patterned resist layer into portions of the second resist layer to form solubility shifted regions in the second resist layer. The method additionally includes removing the solubility shifted regions using a dry development process to form a second patterned resist layer.

In accordance with yet another aspect of the present invention, a method is provided for processing a substrate. The method includes providing a substrate comprising a first resist layer, the first resist layer comprises a photoacid generator and a solubility shifting agent. The method further includes selectively exposing portions of the first resist layer to actinic radiation through a photomask to activate the photoacid generator, and developing the first resist layer to remove the exposed portions to form a first relief pattern. The method additionally includes depositing a second resist layer to fill openings in the first relief pattern, activating the solubility shifting agent, diffusing the solubility shifting agent into the second resist layer to form solubility shifted regions in the second resist layer, and removing the solubility shifted region using a dry development process.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1I illustrate cross-sectional views of process steps for patterning a substrate using solubility shifting agent and dry development, in accordance with an embodiment;

FIG. 2 illustrates a cross-sectional view of a diffusion process variation where solubility shifting agent diffuses through a first resist layer, in accordance with an embodiment;

FIGS. 3A-3B illustrate cross-sectional views of alternative dry development processes using gas development and light beam development, respectively, in accordance with an embodiment;

FIGS. 4A-4C illustrate schematic representations of self-immolative polymer depolymerization mechanisms in response to external stimuli, in accordance with an embodiment;

FIGS. 5A-5H illustrate cross-sectional views of process steps for patterning a substrate using photoresist materials with pre-incorporated solubility shifting agents, in accordance with an embodiment;

FIGS. 6A-6B illustrate cross-sectional views of a process variation for patterning a substrate using solubility shifting agent and dry development, in accordance with an embodiment;

FIG. 7 illustrates a process flow diagram of method steps for patterning a substrate using a solubility shifting agent coating process, in accordance with an embodiment;

FIG. 8 illustrates a process flow diagram of method steps for patterning a substrate using photoresist materials with pre-incorporated solubility shifting agents, in accordance with an embodiment; and

FIG. 9 illustrates a process flow diagram of a method variation for patterning a substrate using a solubility shifting agent coating process, in accordance with an embodiment.

### DETAILED DESCRIPTION OF ILLUSTRATIVE EMBODIMENTS

Methods utilizing solubility shifting compositions can achieve multiple high-resolution pattern features from a single lithography exposure. These methods reduce process steps compared to conventional multi-exposure approaches. In various embodiments, a solubility shifting composition may diffuse from a first resist material into an adjacent second resist material to form solubility shifted regions. The diffusion distance may be precisely controlled to define feature dimensions beyond conventional lithographic resolution limits. The solubility shifted regions may exhibit shifted solubility compared to original resist material, allowing selective removal during a subsequent development process. Conventional wet development process includes using aqueous or organic solvents to selectively dissolve these solubility shifted regions. However, the wet development process may create capillary forces between closely spaced features, leading to pattern collapse and increased defectivity, especially when feature dimensions scale to nanometers.

In various embodiments of this disclosure, methods using dry development processes may overcome limitations of conventional wet development techniques to remove the solubility shifted regions. In one or more embodiments, the dry development processes eliminate liquid-induced capillary effects and comprise thermal treatment, reactive gas exposure, or plasma etching to remove the solubility shifted regions. These processes can reduce pattern collapse and defectivity to maintain pattern fidelity at advanced technology nodes.

In various embodiments, the second resist material may comprise self-immolative polymers. These specialized macromolecules may undergo controlled depolymerization through cascade reactions when exposed to specific stimuli. The depolymerization process enables efficient material removal through dry development while maintaining the integrity of unmodified regions. The controlled polymer breakdown allows precise pattern formation without liquid-induced pattern degradation.

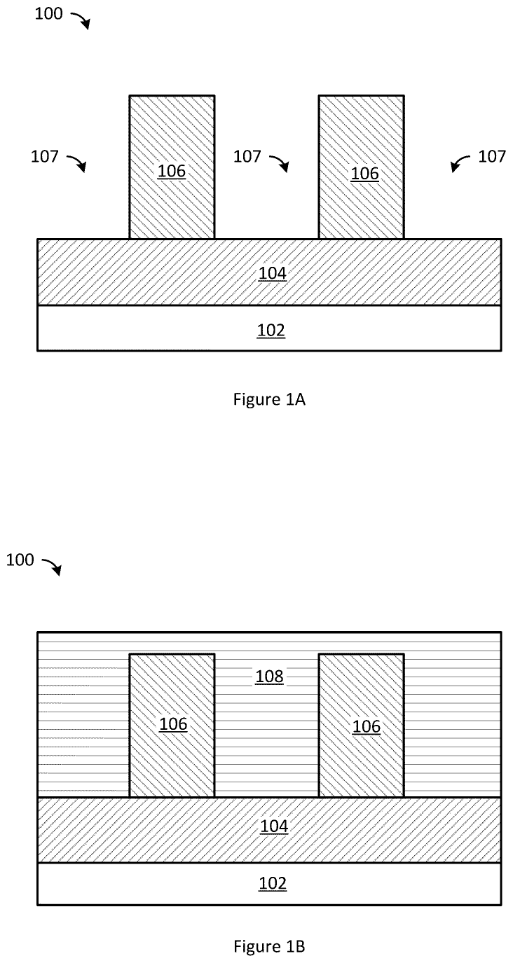

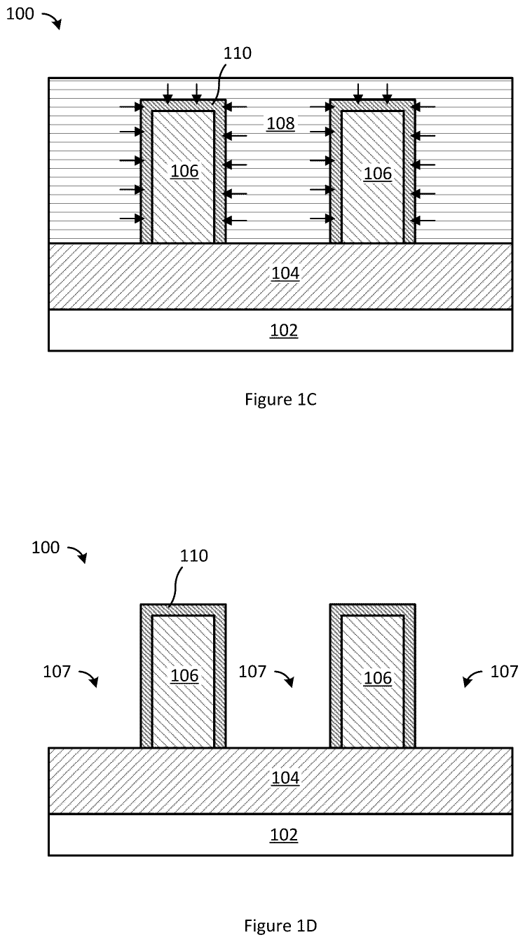

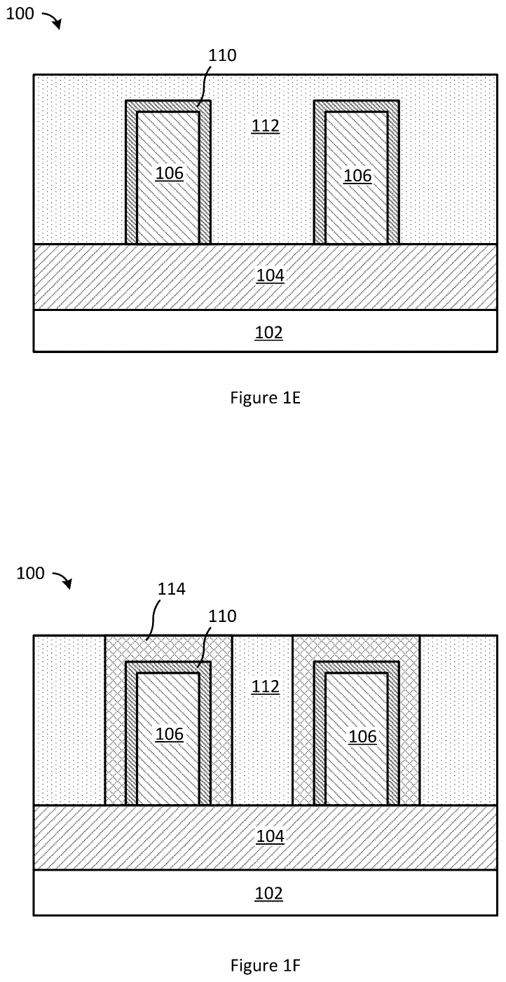

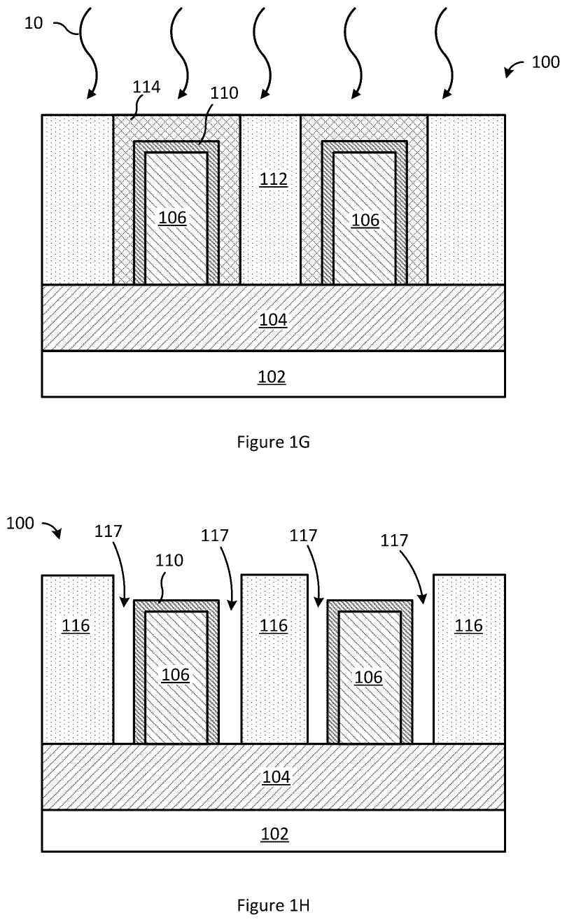

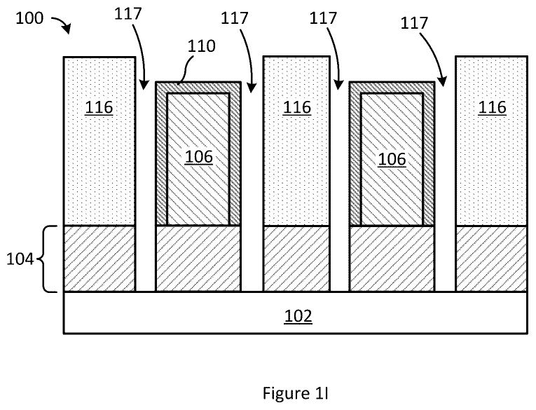

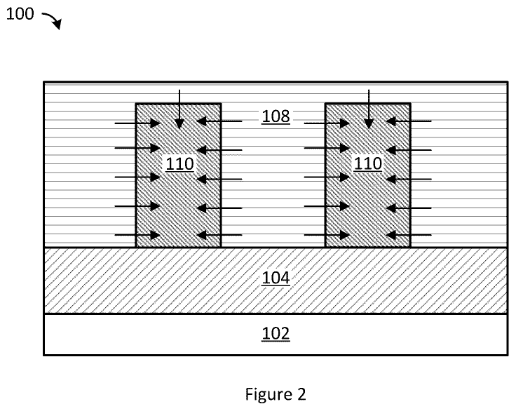

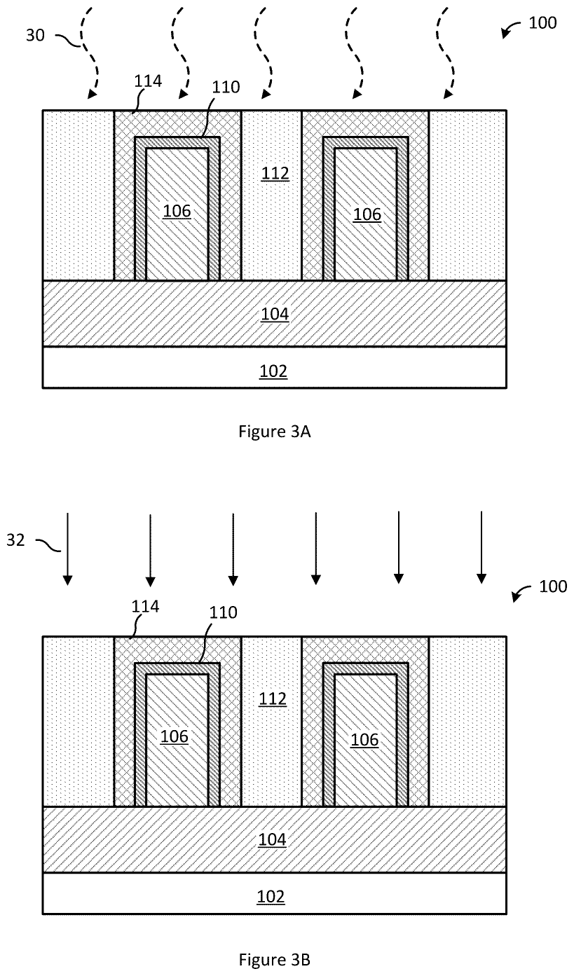

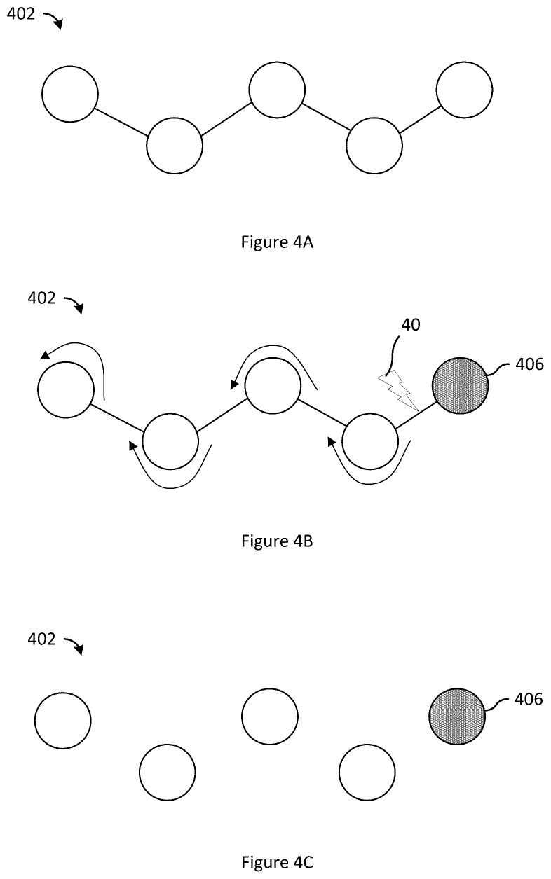

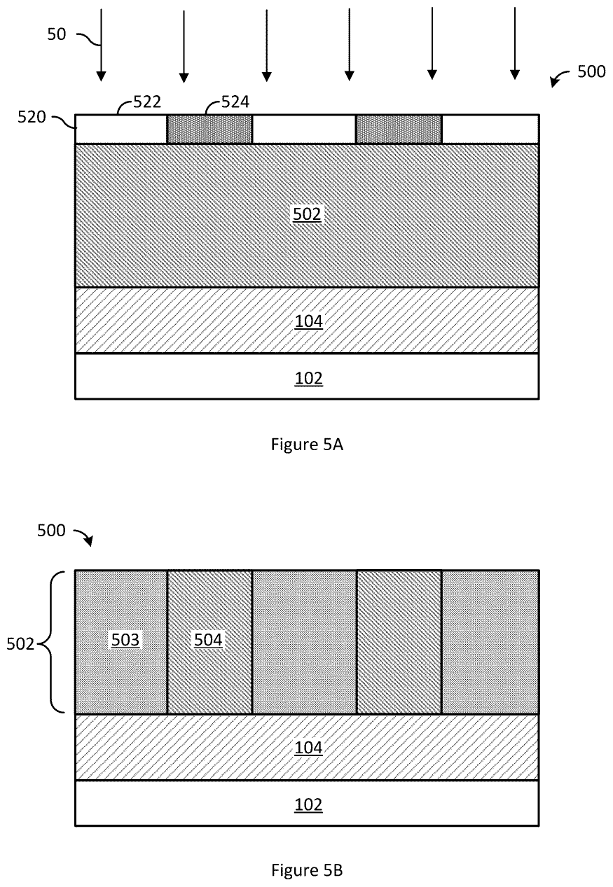

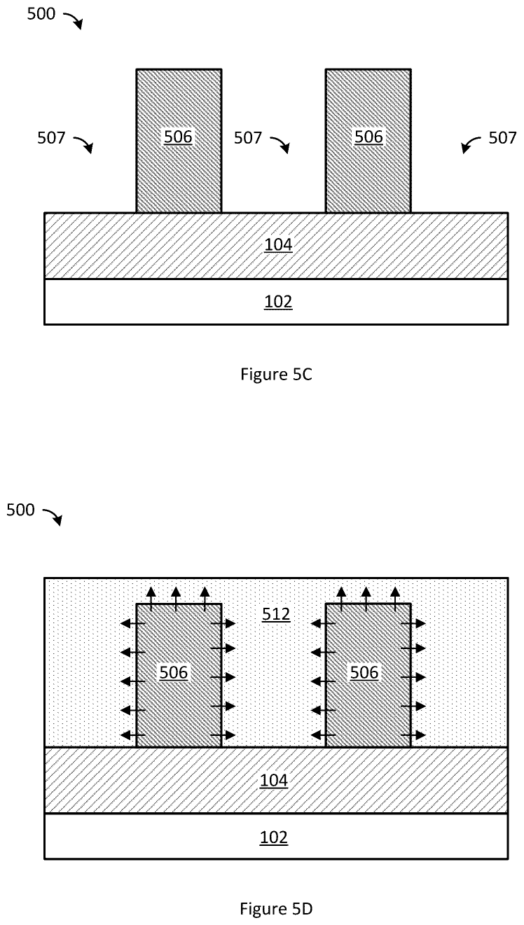

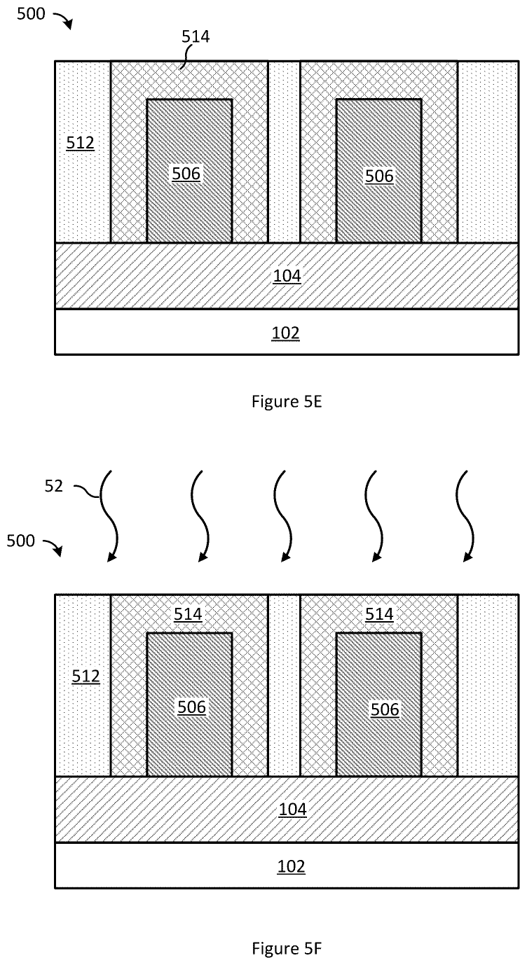

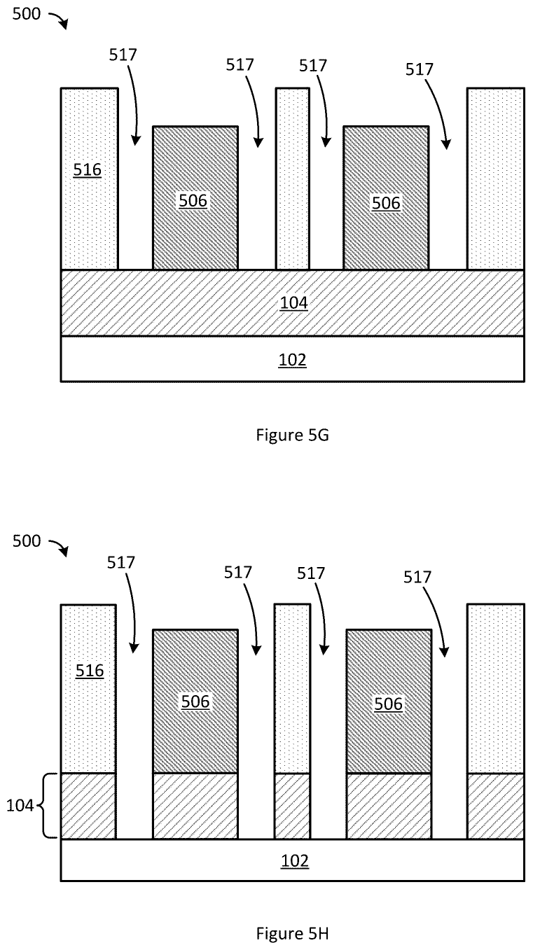

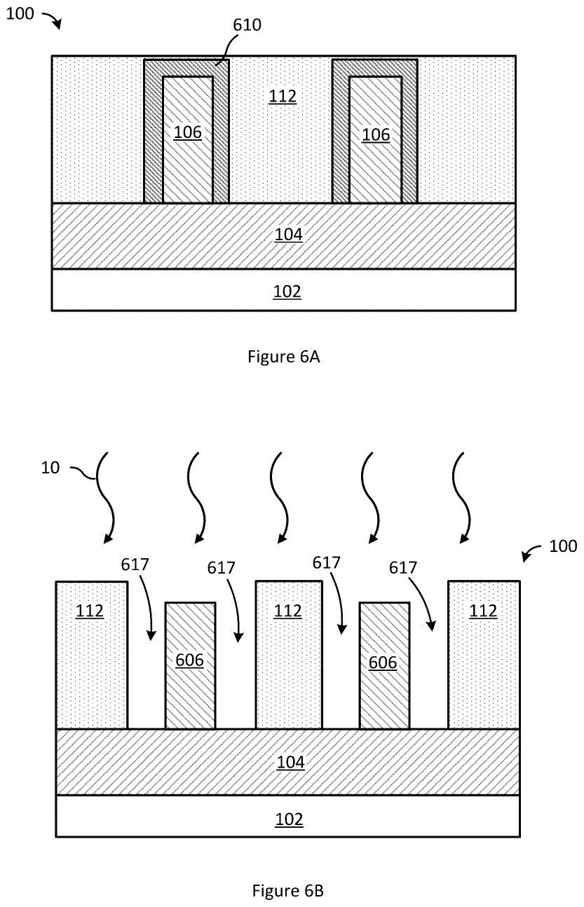

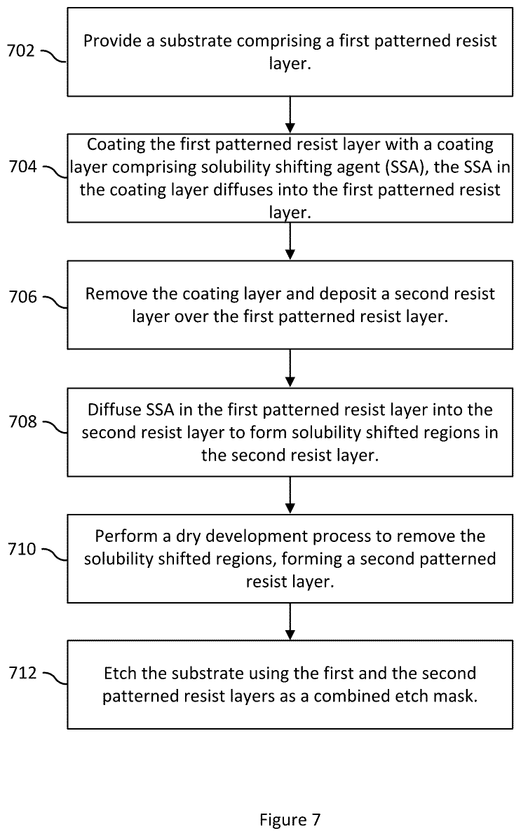

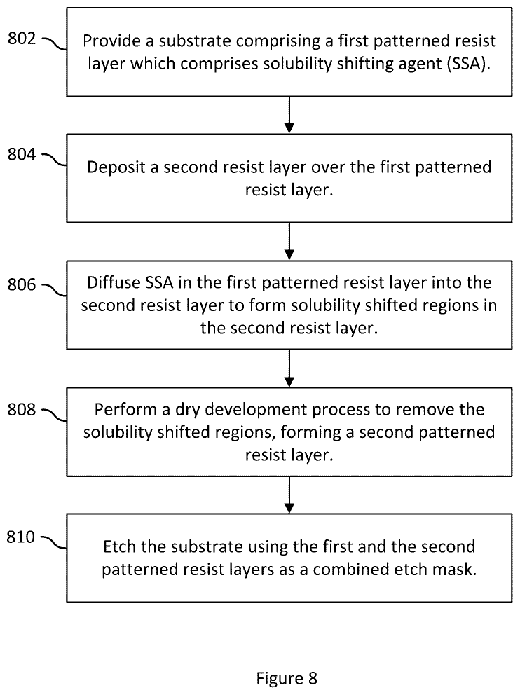

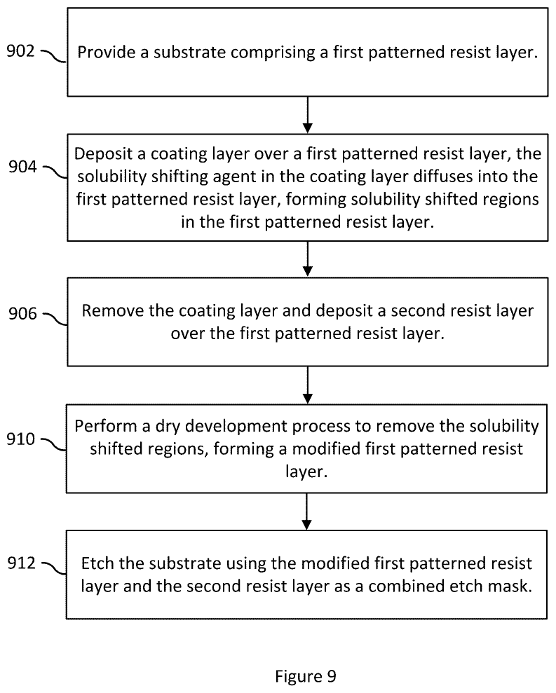

FIGS. 1A-1I illustrate process steps of an embodiment method for patterning a substrate using solubility shifting agent (SSA) and dry development process. FIG. 2 shows a variation of the process where SSA diffuses through a first resist layer. FIGS. 3A and 3B demonstrate alternative dry development techniques using gas and light development processes, respectively. FIGS. 4A-4C show the mechanism of self-immolative polymers undergoing rapid depolymerization in response to stimuli. FIGS. 5A-5H describe another embodiment method where SSA pre-exists inside a first resist layer rather than being applied as a coating. FIGS. 6A-6B provide a process variation for patterning a substrate using SSA and dry development process. FIG. 7 provides a process flow diagram illustrating steps of patterning a substrate using SSA as a coating layer. FIG. 8 provides a process flow diagram illustrating steps of patterning a substrate where SSA is incorporated within the first resist layer. FIG. 9 provides a process flow diagram illustrating a process variation of patterning a substrate using SSA as a coating layer.

FIGS. 1A-1I illustrate cross-sectional views of process steps for patterning a substrate using solubility shifting agent and dry development process, in accordance with one embodiment.

In FIG. 1A, a substrate 100 comprising a substrate layer 102, a layer to-be-etched 104 deposited over the substrate layer 102, and a first patterned resist layer 106 deposited over a layer to-be-etched 104 is provided in a process chamber. In various embodiments, the substrate layer 102 may comprise a bulk substrate such as a blank silicon wafer, a silicon-on-insulator (SOI) wafer, or any of various other semiconductor substrates. The substrate layer 102 may also be coated or layered with any number of additional materials, including compound semiconductors, metal or metal oxides, or metal nitrides. The substrate layer 102 may include any material portion or structure of a device, particularly a semiconductor or other electronics device. In various embodiments, the layer to-be-etched 104 may comprise any material commonly used in semiconductor device fabrication. The layer to-be-etched 104 may include dielectric materials such as silicon oxide, silicon nitride, silicon oxynitride, or low-k dielectric materials, or conductive materials such as polysilicon, metals, metal alloys, metal nitrides, or metal silicides.

In various embodiments, the first patterned resist layer 106 is also referred to as a first relief pattern which may be formed through a lithography process. In various embodiments, the process may include depositing a resist material over the layer to-be-etched 104, forming a pattern in the resist material using photolithography, and etching the resist material through the pattern to form openings 107. The etching may comprise dry etching, wet etching, or a combination thereof to achieve desired profile control of the openings 107.

In various embodiments, the first patterned resist layer 106 may be a photoresist, which may be a chemically amplified photosensitive composition that comprises a polymer, a photoacid generator (PAG), or a solvent. In one or more embodiments, the first patterned resist layer 106 may include a polymer. The polymer may be any standard polymer typically used in photoresist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. In various embodiments, monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the resist layer. As will be appreciated by one having ordinary skill in the art, various protecting groups may be used for this reason. In one or more embodiments, the acid-labile groups may comprise tertiary alkyl ester groups, secondary or tertiary aryl ester groups, secondary or tertiary ester groups having a combination of alkyl and aryl groups, tertiary alkoxy groups, acetal groups, or ketal groups. The acid-labile groups may be also commonly referred to in the art as “acid-decomposable groups”, “acid-cleavable groups”, “acid-cleavable protecting groups”, “acid-labile protecting groups”, “acid-leaving groups”, and “acid-sensitive groups”.

In various embodiments, the polymer comprising acid-labile groups that decompose to form carboxylic acids. The acid-labile groups may comprise a tertiary ester group of the formula —C(O)OC(R¹)₃ or an acetal group of the formula —C(O)OC(R²)₂OR³. In some embodiments, R¹ may be each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, e.g., linear C₁₋₆ alkyl, branched C₃₋₆ alkyl, or monocyclic or polycyclic C₃₋₁₀ cycloalkyl. Each R¹ may comprise one or more groups chosen from —O—, —C(O)—, —C(O)—O—, or —S—, and any two R¹ groups together may form a ring. In various embodiments, R² may be independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, linear C₁₋₆ alkyl, branched C₃₋₆ alkyl, or monocyclic or polycyclic C₃₋₁₀ cycloalkyl. Each R² may optionally comprise one or more groups chosen from —O—, —C(O)—, —C(O)—O—, or —S—, and the R² groups together may form a ring. In various embodiments, R³ may be linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, e.g., linear C₁₋₆ alkyl, branched C₃₋₆ alkyl, or monocyclic or polycyclic C₃₋₁₀ cycloalkyl. R³ may comprise one or more groups chosen from —O—, —C(O)—, —C(O)—O—, or —S—, and one R² together with R³ may form a ring. The monomer may be a vinyl aromatic, (meth)acrylate, or norbornyl monomer. In various embodiments, polymerized units containing carboxylic acid-generating acid-labile groups may comprise between 10 and 100 mole percent of the total polymer composition. In an embodiment, these units may comprise between 10 and 90 mole percent of the total polymerized units. In another embodiment, these units may comprise between 30 and 70 mole percent of the total polymerized units, with all mole percentages calculated based on total polymerized units in the polymer.

In various embodiments, the polymer may comprise polymerized monomers containing acid-labile groups that decompose to form alcohol or fluoroalcohol functionalities on the polymer backbone. The groups may comprise an acetal group of the formula —COC(R²)₂OR³—, or a carbonate ester group of the formula —OC(O)O—, wherein R² and R³ are as defined above. The monomer may be a vinyl aromatic, (meth)acrylate, or norbornyl monomer. In various embodiments, the polymer may comprise between 10 and 90 mole percent of polymerized units containing acid-labile groups that generate alcohol or fluoroalcohol functionalities upon deprotection. In an embodiment, the polymer may comprise between 30 and 70 mole percent of these polymerized units, with the mole percentages calculated based on total polymerized units in the polymer.

In some embodiments, the first patterned resist layer 106 may be a photoresist comprising a photoacid generator. The photoacid generator may be a compound capable of generating an acid upon irradiation with actinic rays or radiation. In various embodiments, the photoacid generator may comprise compounds that generate acid upon exposure to actinic radiation. The photoacid generator may include compounds used as photoinitiators for cationic polymerization, photoinitiators for radical polymerization, photodecoloring agents for dyes, photodiscoloring agents, or compounds used in microresists. In one or more embodiments, combinations of different photoacid generators are used. In some embodiments, the photoacid generator may include a diazonium salt, a phosphonium salt, a sulfonium salt, an iodonium salt, imidosulfonate, oxime sulfonate, diazodisulfone, disulfone, or o-nitrobenzyl sulfonate.

In some embodiments, the photoacid generators may comprise onium salts such as triphenylsulfonium trifhioromethanesulfonate, (p-tert-butoxyphenyl)diphenylsulfonium trifhioromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, or di-t-butyphenyliodonium camphorsulfonate. In various embodiments, the photoacid generators may comprise non-ionic sulfonates, or sulfonyl compounds. In some embodiments, the photoacid generators may comprise nitrobenzyl derivatives such as 2-nitrobenzyl-p-toluenesulfonate, 2,6-dinitrobenzyl-p-toluenesulfonate, or 2,4-dinitrobenzyl-p-toluenesulfonate. In some embodiments, the photoacid generators may comprise sulfonic acid esters such as 1,2,3-tris(methanesulfonyloxy)benzene, 1,2,3-tris(trifluoromethanesulfonyloxy)benzene, or 1,2,3-tris(p-toluenesulfonyloxy)benzene. In some embodiments, the photoacid generators may comprise diazomethane derivatives such as bis(benzenesulfonyl)diazomethane, or bis(p-toluenesulfonyl)diazomethane. In some embodiments, the photoacid generators may comprise glyoxime derivatives such as bis-O-(p-toluenesulfonyl)-a-dimethylglyoxime, or bis-O-(n-butanesulfonyl)-a-dimethylglyoxime. In some embodiments, the photoacid generators may comprise sulfonic acid ester derivatives of an N-hydroxyimide compound, for example, N-hydroxy succinimide methanesulfonic acid ester, or N-hydroxysuccinimide trifluoromethanesulfonic acid ester. In some embodiments, the photoacid generators may comprise halogen-containing triazine compounds such as 2-(4-methoxyphenyl)-4,6-bis(trichloromethyl)-1,3,5-triazine, or 2-(4-methoxynaphthyl)-4,6-bis(trichloromethyl)-1,3,5-triazine. In one or more embodiments, the photoacid generators may further comprise sulfonated esters and sulfonyloxy ketones, nitrobenzyl esters, s-triazine derivatives, benzoin tosylate, t-butylphenyl a-(p-toluenesulfonyloxy)-acetate, or t-butyl a-(p-toluenesulfonyloxy)-acetate. In one embodiment, the photoacid generators may comprise onium salts, which may comprise an anion having a sulfonate group or a non-sulfonate type group, such as a sulfonamidate group, a sulfonimidate group, a methide group, or a borate group.

In various embodiments, the first patterned resist layer 106 may further comprise a resin which may comprise a fluorine atom, a silicon atom, a basic compound, a surfactant, an onium carboxylate, dye, a plasticizer, a photosensitizer, a light absorbent, an alkali-soluble resin, a dissolution inhibitor, and a compound for accelerating dissolution in a developer.

In one or more embodiments, the first patterned resist layer 106 may have a thickness of about 300 to 3000 Å. The openings 107 separating the features may leave portions of the layer to-be-etched 104 exposed.

In some embodiments, the first patterned resist layer 106 may be stabilized prior to coating with the solubility shifting agent in subsequent processes. Various resist stabilization techniques, also known as freeze processes, such as ion implantation, UV curing, thermal hardening, thermal curing and chemical curing may be used to stabilize the first patterned resist layer 106.

In FIG. 1B, a coating layer 108 comprising solubility shifting agent may be deposited over the first patterned resist layer 106. The coating layer 108 may fully cover the first patterned resist layer 106. In various embodiments, the solubility shifting agent in the coating layer 108 may be a material that is absorbed into the first patterned resist layer 106 via a bake, and in some instances herein may be referred to as an “absorbed material”. The process of absorbing the solubility shifting agent into the resist layer is described in detailed below.

The composition of the solubility shifting agent may depend on the tone of the first patterned resist layer 106. The solubility shifting agent may be any chemical that activates with light or heat. In some embodiments, when the first patterned resist layer 106 is a positive tone developed (PTD) photoresist, the solubility shifting agent may include an acid or thermal acid generator (TAG). The acid or generated acid in the case of a TAG should be sufficient with heat to cause cleavage of the bonds of acid-decomposable groups of the polymer in a surface region of the first patterned resist layer 106 to cause increased solubility of the photoresist polymer in a specific developer to be applied. The acid or TAG is typically present in the composition in an amount of from about 0.1 to 20 wt % based on the total solids of the solubility shifting agent.

In various embodiments, the acids in the solubility shifting agent may be organic acids including non-aromatic acids and aromatic acids, each of which can optionally have fluorine substitution. In some embodiments, the organic acids may comprise carboxylic acids, alkanoic acids, formic acid, acetic acid, propionic acid, butyric acid, dichloroacetic acid, trichloroacetic acid, perfluoroacetic acid, perfluorooctanoic acid, oxalic acid malonic acid, or succinic acid. In some embodiments, the organic acids may also comprise hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid or dimethylphosphinic acid. In some embodiments, the organic acids may also comprise sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, or 1-heptanesulfonic acid.

In various embodiments, the aromatic acids that are free of fluorine may comprise general formula (I):

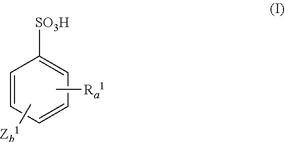

R¹ may independently represent a substituted or unsubstituted C₁-C₂₀ alkyl group, a substituted or unsubstituted C₅-C₂₀ aryl group or a combination thereof, optionally containing one or more group chosen from carbonyl, carbonyloxy, sulfonamido, ether, thioether, a substituted or unsubstituted alkylene group, or a combination thereof. Z¹ may independently represent a group chosen from carboxyl, hydroxy, nitro, cyano, C₁ to C₅ alkoxy, formyl and sulfonic acid. a and b are independently an integer from 0 to 5; and a+b is 5 or less.

Other exemplary aromatic acids may be of general formula (II):

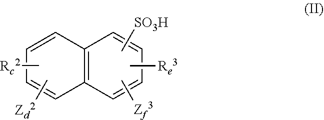

wherein: R² and R³ may each independently represent a substituted or unsubstituted C₁-C₂₀ alkyl group, a substituted or unsubstituted C₅-C₁₆ aryl group or a combination thereof, optionally containing one or more group chosen from carbonyl, carbonyloxy, sulfonamido, ether, thioether, a substituted or unsubstituted alkylene group, or a combination thereof; Z² and Z³ each independently represents a group chosen from carboxyl, hydroxy, nitro, cyano, C₁ to C₅ alkoxy, formyl and sulfonic acid; c and d are independently an integer from 0 to 4; c+d is 4 or less; e and f are independently an integer from 0 to 3; and e+f is 3 or less.

Additional aromatic acids that may be included in the solubility shifting agent include those of general formula (III) or (IV):

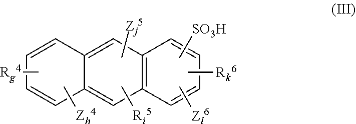

wherein: R⁴, R⁵ and R⁶ each independently represents a substituted or unsubstituted C₁-C₂₀ alkyl group, a substituted or unsubstituted C₅-C₁₂ aryl group or a combination thereof, optionally containing one or more group chosen from carbonyl, carbonyloxy, sulfonamido, ether, thioether, a substituted or unsubstituted alkylene group, or a combination thereof; Z⁴, Z⁵ and Z⁶ each independently represents a group chosen from carboxyl, hydroxy, nitro, cyano, C₁ to C₅ alkoxy, formyl and sulfonic acid; g and h are independently an integer from 0 to 4; g+h is 4 or less; i and j are independently an integer from 0 to 2; i+j is 2 or less; k and 1 are independently an integer from 0 to 3; and k+1 is 3 or less.

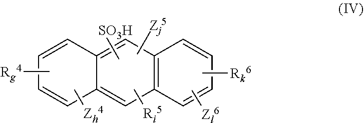

wherein: R⁴, R⁵ and R⁶ each independently represents a substituted or unsubstituted C₁-C₂₀ alkyl group, a substituted or unsubstituted C₅-C₁₂ aryl group or a combination thereof, optionally containing one or more group chosen from carbonyl, carbonyloxy, sulfonamido, ether, thioether, a substituted or unsubstituted alkylene group, or a combination thereof; Z⁴, Z⁵ and Z⁶ each independently represents a group chosen from carboxyl, hydroxy, nitro, cyano, C₁ to C₅ alkoxy, formyl and sulfonic acid; g and h are independently an integer from 0 to 4; g+h is 4 or less; i and j are independently an integer from 0 to 1; i+j is 1 or less; k and 1 are independently an integer from 0 to 4; and k+1 is 4 or less.

Suitable aromatic acids may alternatively be of the general formula (V):

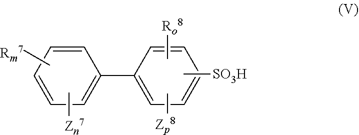

wherein: R⁷ and R⁸ each independently represents a substituted or unsubstituted C₁-C₂₀ alkyl group, a substituted or unsubstituted C₅-C₁₄ aryl group or a combination thereof, optionally containing one or more group chosen from carboxyl, carbonyl, carbonyloxy, sulfonamido, ether, thioether, a substituted or unsubstituted alkylene group, or a combination thereof; Z⁷ and Z⁸ each independently represents a group chosen from hydroxy, nitro, cyano, C₁ to C₅ alkoxy, formyl and sulfonic acid; m and n are independently an integer from 0 to 5; m+n is 5 or less; o and p are independently an integer from 0 to 4; and o+p is 4 or less.

Additionally, exemplary aromatic acids may further have general formula (VI):

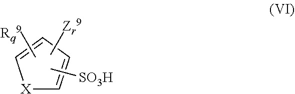

wherein: X is O or S; R⁹ independently represents a substituted or unsubstituted C₁-C₂₀ alkyl group, a substituted or unsubstituted C₅-C₂₀ aryl group or a combination thereof, optionally containing one or more group chosen from carbonyl, carbonyloxy, sulfonamido, ether, thioether, a substituted or unsubstituted alkylene group, or a combination thereof; Z⁹ independently represents a group chosen from carboxyl, hydroxy, nitro, cyano, C₁ to C₅ alkoxy, formyl and sulfonic acid; q and r are independently an integer from 0 to 3; and q+r is 3 or less.

In one or more embodiments, the acid in the solubility shifting agent may be a free acid having fluorine substitution. Suitable free acids having fluorine substitution may be aromatic or nonaromatic. In some embodiments, free acid having fluorine substitution that may be used as solubility shifting agent include, but are not limited to the following:

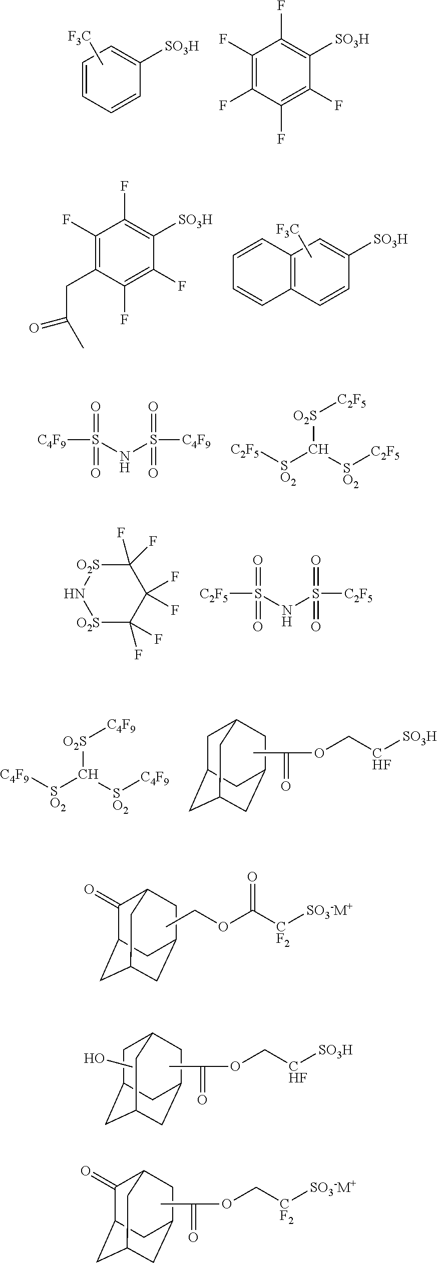

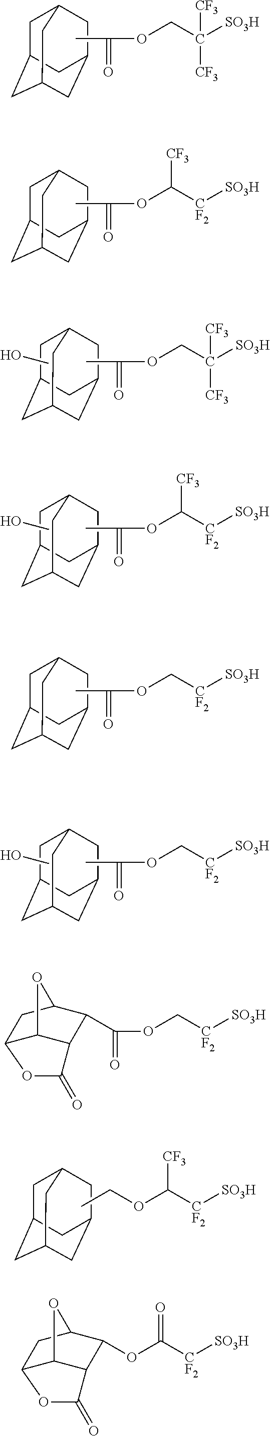

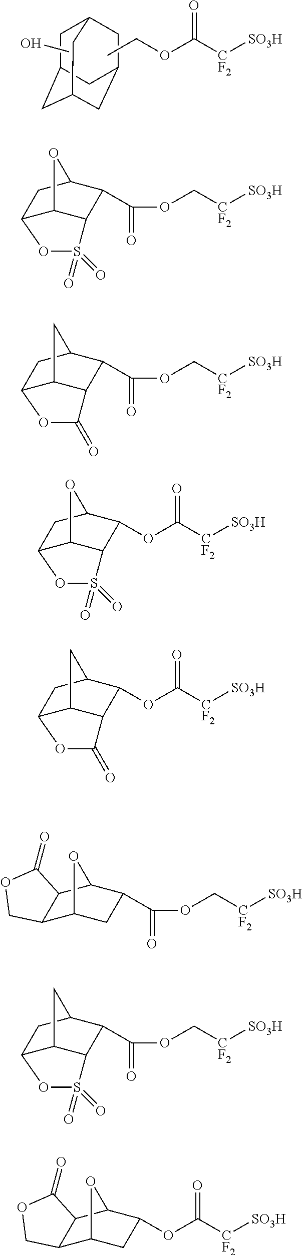

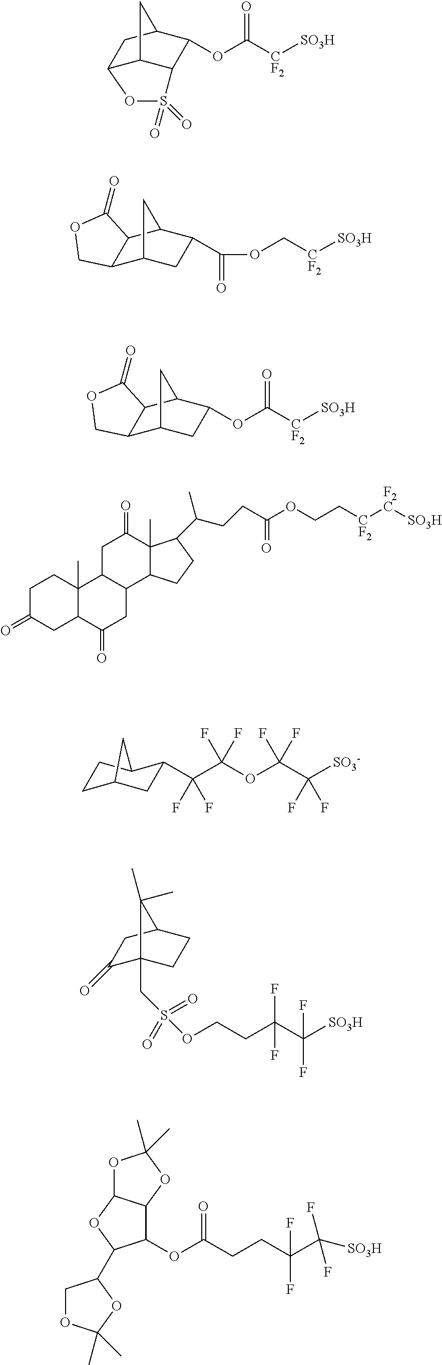

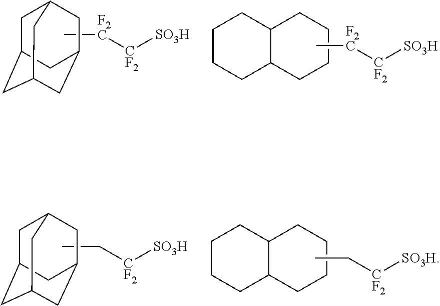

In various embodiments, the solubility shifting agent may comprise a TAG that produces non-polymeric acid species as described above. In one or more embodiments, the TAG may comprise ionic compounds or non-ionic compounds.

In one or more embodiments, the non-ionic compounds of TAG may comprise cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof.

In one or more embodiments, the ionic compounds of TAG may comprise dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, or benzenesulfonate salts. In some embodiments, the TAG may comprise p-toluenesulfonic acid ammonium salts, or heteroaryl sulfonate salts.

In some embodiments, the TAG may be ionic with a reaction scheme for generation of a sulfonic acid as shown below:

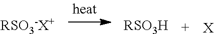

wherein RSO₃⁻ is the TAG anion and X⁺ is the TAG cation comprising an organic cation. The TAG cation may be a nitrogen-containing cation of the general formula (VII):

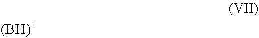

which is the monoprotonated form of a nitrogen-containing base B. In one or more embodiments, the nitrogen-containing bases B may comprise optionally substituted amines such as ammonia, difluoromethylammonia, C₁₋₂₀ alkyl amines, and C₃₋₃₀ aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B may be optionally substituted, for example, with one or more group chosen from alkyl, aryl, halogen atom (e.g., fluorine), cyano, nitro and alkoxy. In various embodiments, the base B may be a heteroaromatic base.

In various embodiments, the base B may have a pKa from 0 to 5.0, or between 0 and 4.0, or between 0 and 3.0, or between 1.0 and 3.0. As used herein, the term “pKa” is used in accordance with its art-recognized meaning, that is, pKa is the negative log (to the base 10) of the dissociation constant of the conjugate acid (BH)⁺ of the basic moiety (B) in aqueous solution at about room temperature. In certain embodiments, base B has a boiling point less than about 170° C., or less than about 160° C., 150° C., 140° C., 130° C., 120° C., 110° C., 100° C., or 90° C.

In some embodiments, the nitrogen-containing cations (BH)⁺ may include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

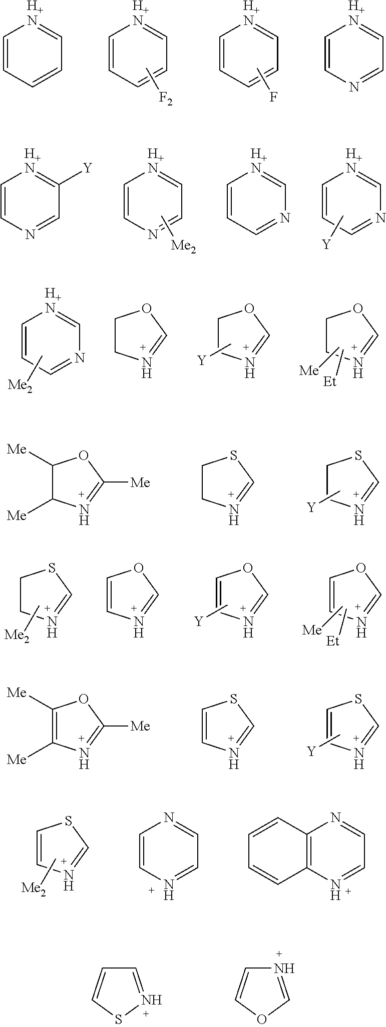

in which Y may be alkyl, e.g., methyl or ethyl.

In particular embodiments, the solubility shifting agent may be an acid such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; an acid generator such as triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; or a combination thereof.

Alternatively, when the first patterned resist layer 106 is a negative tone developed (NTD) photoresist, the solubility shifting agent may comprise a base or base generator. In such embodiments, suitable solubility shifting agents may include, but are not limited to, hydroxides, carboxylates, amines, imines, amides, and mixtures thereof. In various embodiments, the bases in the solubility shifting agent may comprise ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, or tetraethylammonium phosphate. In some embodiments, the amines may comprise aliphatic amines, cycloaliphatic amines, aromatic amines or heterocyclic amines. The amine may be a primary, secondary or tertiary amine. The amine may be a monoamine, diamine or polyamine. In certain embodiments, the amines may include C₁₋₃₀ organic amines, imines, amides, a C₁₋₃₀ quaternary ammonium salt of a strong base (e.g., a hydroxide or alkoxide), or a weak base (e.g., a carboxylate). In various embodiments, the bases may include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-butyl 1,3-dihydroxy-2-(hydroxymethyl)propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate. In another embodiment, the amine is a hydroxyamine. In various embodiments, the hydroxyamines may include hydroxyamines having one or more hydroxyalkyl groups each having 1 to about 8 carbon atoms, and e.g. 1 to about 5 carbon atoms such as hydroxymethyl, hydroxyethyl and hydroxybutyl groups. In various embodiments, the hydroxy amines may include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol, or triethanolamine.

In various embodiments, the solubility shifting agent may comprise a thermal base generator. The thermal base generator may form a base upon heating above a first temperature, typically about 140° C. or higher. The thermal base generator may comprise a functional group such as an amide, sulfonamide, imide, imine, O-acyl oxime, benzoyloxycarbonyl derivative, quarternary ammonium salt, nifedipine, or carbamate.

In one or more embodiments, the thermal base generators may comprise o-{(.beta.-(dimethylamino)ethyl)aminocarbonyl}benzoic acid, o-{(.gamma.-(dimethylamino)propyl)aminocarbonyl}benzoic acid, 2,5-bis{(.beta.-(dimethylamino)ethyl)aminocarbonyl}terephthalic acid, 2,5-bis{(.gamma.-(dimethylamino)propyl)aminocarbonyl}terephthalic acid, 2,4-bis{(.beta.-(dimethylamino)ethyl)aminocarbonyl}isophthalic acid, or 2,4-bis{(.gamma.-(dimethylamino)propyl)aminocarbonyl}isophthalic acid.

In one or more embodiments, the solubility shifting agent may comprise a solvent. As described above, in some embodiments the solubility shifting agent may be absorbed into the first patterned resist layer 106. Accordingly, the solvent may be any suitable solvent that may facilitate absorption into the resist layer, provided that it does not dissolve the resist layer. The solvent may be chosen from water, organic solvents and mixtures thereof. In some embodiments, the solvent may include an organic-based solvent comprising one or more organic solvents. In various embodiments, the organic-based solvent may comprise greater than 50 wt % organic solvent based on total solvents of the solubility shifting agent composition, more typically greater than 90 wt %, greater than 95 wt %, greater than 99 wt % or 100 wt % organic solvents, based on total solvents of the solubility shifting agent compositions. The solvent component may be present in an amount of from 90 to 99 wt % based on the solubility shifting agent composition.

In various embodiments, the organic solvents for the solubility shifting agent composition may comprise alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C₄-C₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C₅-C₉ fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; and mixtures containing one or more of these solvents.

The solvent included in the absorbed material may depend on the composition and tone of the first patterned resist layer 106. When the first patterned resist layer 106 is formed from a (meth)acrylate polymer, as is typical for ArF resists, and the resist is developed as a PTD resist, the solvent may comprise one or more polar organic solvents. In some embodiments, a solubility shifting agent absorbed into a PTD first resist may include a polar solvent such as methyl isobutyl carbinol (MIBC). In other embodiments, the solubility shifting agent may also include aliphatic hydrocarbons, esters, and ethers as cosolvents such as, for example, decane, isobutyl isobutyrate, isoamyl ether, and combinations thereof. In particular embodiments, the solvent includes MIBC and a cosolvent. In such embodiments, the MIBC may be included in the solvent in an amount ranging from 60 to 99%, based on the total volume of solvent. Accordingly, the cosolvent may be included in amount ranging from 1 to 40%, based on the total volume of solvent.

In some embodiments, the first patterned resist layer 106 may be formed from a vinyl aromatic-based polymer, such as KrF and EUV photoresists, and the resist is developed as a PTD resist, the solvent may comprise one or more non-polar organic solvents. In various embodiments, the non-polar organic solvents may comprise greater than 50 wt % of combined non-polar organic solvents based on total solvents of the solubility shifting agent composition, more typically greater than 70 wt %, greater than 85 wt % or 100 wt %, combined non-polar organic solvents, based on total solvents of the solubility shifting agent composition. The non-polar organic solvents may be present in the solvent in a combined amount of from 70 to 98 wt %, e.g. 80 to 95 wt %, in another example from 85 to 98 wt %, based on the solvent.

In various embodiments, the non-polar solvents in solubility shifting agent may comprise ethers, hydrocarbons, and combinations thereof, with ethers being used in one embodiment. Suitable ether solvents may include, for example, alkyl monoethers and aromatic monoethers having a total carbon number of from 6 to 16. Suitable alkyl monoethers may include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether. Suitable aromatic monoethers may include, for example, anisole, ethylbenzyl ether, diphenyl ether, dibenzyl ether and phenetole. Suitable aliphatic hydrocarbons may include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons may include, for example, benzene, toluene, and xylene.

In some embodiments, the solvent may further comprise one or more alcohol and/or ester solvents. For certain compositions, an alcohol and/or ester solvent may provide enhanced solubility with respect to the solid components of the composition. Suitable alcohol solvents may include, for example: straight, branched or cyclic C₄₋₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C₅₋₉ fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent may comprise C₄₋₉ monohydric alcohol, e.g., 4-methyl-2-pentanol. Suitable ester solvents may include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent may be present in a combined amount of from 2 to 50 wt %, more typically in an amount of from 2 to 30 wt %, based on the solvent.

In some embodiments, the solvent may also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, may be present in a combined amount of from 1 to 20 wt % based on the solvent.

In alternative embodiments, the first patterned resist layer 106 may be formed from a vinyl aromatic-based polymer. An embodiment organic-based solvent may include one or more monoether solvents in a combined amount of from 70 to 98 wt % based on the solvent, and one or more alcohol and/or ester solvents in a combined amount of from 2 to 30 wt % based on the solvent. The solvent may be present in the overcoat composition in an amount of from 90 to 99 wt %, e.g. from 95 to 99 wt %, based on the overcoat composition.

In embodiments in which the first patterned resist layer 106 is an NTD resist, suitable organic solvents may comprise n-butyl acetate, 2-heptanone, propylene glycol methyl ether, or propylene glycol methyl ether acetate.

In some embodiments, to properly coat the first relief pattern, the solubility shifting agent in the coating layer 108 may include a matrix polymer. Any matrix polymer commonly used in the art may be included in the solubility shifting material. The matrix polymer should have good solubility in a solvent that does not dissolve the first patterned resist layer 106. In various embodiments, the matrix polymer may be formed from one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbornenes; and combinations thereof.

In some embodiments, the polymer may comprise one or more functional groups such as hydroxy, acid groups such as carboxyl, sulfonic acid and sulfonamide, silanol, fluoroalcohol such as hexafluoroisopropyl alcohol [—C(CF₃)₂OH], anhydrates, lactones, esters, ethers, allylamine, or pyrrolidones. In some embodiments, the polymer may be a homopolymer or a copolymer having a plurality of distinct repeat units, for example, two, three, four or more distinct repeat units. In one embodiment, the repeat units of the polymer may be formed from (meth)acrylate monomers, (vinyl)aromatic monomers, (meth) acrylate monomers, or (vinyl) aromatic monomers. In some embodiments when the polymer includes more than one type of repeat unit, it may take the form of a random copolymer.

In particular embodiments, the matrix polymer may comprise a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, or a PHS/methacrylate (MA) copolymer.

In various embodiments, the solubility shifting agent may comprise a single polymer but may optionally include one or more additional polymers. The content of the polymer in the composition may depend, for example, on the target thickness of the layer, with a higher polymer content being used when thicker layer is desired. The polymer is typically present in the pattern solubility shifting agent composition in an amount of from 80 to 99.9 wt %, more typically from 90 to 99 wt %, or 95 to 99 wt %, based on total solids of the solubility shifting agent composition. The weight average molecular weight (Mw) of the polymer may be less than 400,000, e.g. from 3000 to 50,000, in one embodiment from 3000 to 25,000, as measured by GPC versus polystyrene standards. In certain embodiments, the polymer may have a polydispersity index (PDI=Mw/Mn) of 3 or less, e.g. 2 or less, as measured by GPC versus polystyrene standards.

In various embodiments, the polymers in the solubility shifting agent compositions may be commercially available and/or may readily be made by persons skilled in the art. In some embodiments, the polymer may be synthesized by dissolving selected monomers corresponding to units of the polymer in an organic solvent, adding a radical polymerization initiator thereto, and effecting heat polymerization to form the polymer. Examples of suitable organic solvents that can be used for polymerization of the polymer may include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

In various embodiments, solubility shifting agents comprising a matrix polymer may be coated over the first relief pattern according to methods known in the art. In some embodiments, the solubility shifting agent that includes a matrix polymer may be coated over the first relief pattern by spin coating. The solids content of the solubility shifting agent may be tailored to provide a film of a desired thickness of the coating layer 108 over the first relief pattern. In one or more embodiments, the solids content of the solubility shifting agent solution may be adjusted to provide a desired film thickness based upon the specific coating equipment utilized, the viscosity of the solution, the speed of the coating tool and the amount of time allowed for spinning.

In one or more embodiments, the solubility shifting agent may comprise an active material (e.g., an acid, acid generator, base, or base generator), a solvent, and a matrix polymer as previously described. In some embodiments, a formulation for such solubility shifting agent may comprise 1 to 10 wt % solids and 90 to 99 wt % solvent, based on the total weight of the solubility shifting agent, where the solids may include the active material and the matrix polymer. Within the solids content, the active material may be included in an amount ranging from about 1 to about 5 wt %.

In various embodiments, the solubility shifting agent may further comprise additives for various purposes, depending on the particular chemistry being used. In some embodiments, a surfactant may be included in the solubility shifting agent. A surfactant may be included in the solubility shifting agent to help with coating quality, especially when needing to fill the openings 107. Any suitable surfactant known in the art may be included in the solubility shifting agent.

In FIG. 1C, the solubility shifting agent in the coating layer 108 may diffuse at a fixed distance into a portion of the first patterned resist layer 106 as indicated by the arrows, forming a diffused layer 110 in the first patterned resist layer 106. In various embodiments, diffusion of the solubility shifting agent into the first patterned resist layer 106 may be achieved by performing a thermal pretreatment such as a bake. The bake may be a soft bake. The temperature and time of the soft bake may depend on the identity of the resist layer, and the desired amount of diffusion of the solubility shifting agent into the resist layer. In some embodiments, a soft bake may be performed for about 30 seconds to about 90 seconds at a temperature ranging from about 50° C. to about 150° C.

In some embodiments, FIG. 2 illustrates that the solubility shifting agent in the coating layer 108 may diffuse through the entire thickness of first patterned resist layer 106. The diffusion of solubility shifting agent may convert the first patterned resist layer 106 to the diffused layer 110. In one or more embodiments, the diffusion depth and profile of the solubility shifting agent may be controlled through process parameters such as temperature, time, and solubility shifting agent concentration to achieve different combinations of surface and through-thickness diffusion.

FIG. 1D illustrates a step of removing the coating layer 108 after formation of the diffused layer 110. In one or more embodiments, the coating layer 108 may be removed by a rinse. The rinse may be accomplished by rinsing the coated substrate with a solvent that dissolves the coating layer 108 but does not dissolve the first patterned resist layer 106. In various embodiments, the rinse may be carried out using any suitable method, for example, by dipping the substrate 100 in a bath filled with the solvent for a fixed time (or dip method), or by raising the solvent on the substrate 100 surface by the effect of a surface tension and keeping it still for a fixed time, thereby dissolving the coating layer 108 (or puddle method). In alternative embodiments, the rinse may be carried out by spraying the solvent on the substrate 100 surface (or spray method), or by continuously ejecting the solvent on the substrate 100 rotating at a constant speed while scanning the solvent ejecting nozzle at a constant rate (or dynamic dispense method).

In FIG. 1E, a second resist layer 112 may be deposited over the first patterned resist layer 106. The second resist layer 112 may be deposited on the layer to-be-etched 104 such that it fills gaps of the first patterned resist layer 106 (or the first relief pattern) and is in contact with the first patterned resist layer 106 or the solubility shifting agent in the diffused layer 110. In one or more embodiments, the second resist layer 112 may completely cover the layer to-be-etched 104, the first patterned resist layer 106, and the diffused layer 110. The second resist layer 112 may be deposited on the substrate according to any suitable method known in the art such as, for example, spin-on deposition or vapor phase treatment.

In one or more embodiments, the second resist layer 112 may comprise a polymer. Suitable polymers of the second resist layer 112 may be as previously described with respect to the polymer defined as the polymer and/or the matrix polymer in the first patterned resist layer 106. In particular embodiments, suitable polymers may be made from monomers comprising p-hydroxystryene, styrene, or t-butyl acrylate. In particular embodiments, the polymer may be made from all three of p-hydroxystyrene, styrene, and t-butylacrylate. The polymer may be prepared from a polymerization reaction including from about 50 to 80% p-hydroxystyrene, from about 10 to 30% styrene, and from about 10 to 30% t-butylacrylate. For example, a polymerization reaction to produce a polymer included in the second resist layer 112 may include p-hydroxystyrene in an amount ranging from a lower limit of one of 50, 55, 60, and 65% to an upper limit of one of 65, 70, 75, and 80%, where any lower limit may be paired with any mathematically compatible upper limit, and styrene and t-butyl acrylate in individual amounts ranging from a lower limit of one of 10, 12, 14, 16, 18, and 20% to an upper limit of one of 20, 22, 24, 26, 28, and 30%, where any lower limit may be paired with any mathematically compatible upper limit.

In some embodiments, the polymer included in the second resist layer 112 may have a weight average molecular weight (Mw) ranging from 1 to 100 kg/mol. For example, in one or more embodiments, the second resist layer 112 may include a polymer having a Mw ranging from a lower limit of one of 1, 2, 5, 10, 15, 20, and 25 kg/mol to an upper limit of one of 25, 50, 75, 80, 90, and 100 kg/mol, where any lower limit may be paired with any mathematically compatible upper limit. A polymer having such Mw may exhibit desired solubility characteristics, such as, in particular, the dissolution rate.

In one or more embodiments, the second resist layer 112 may comprise self-immolative polymers. In one or more embodiments, the self-immolative polymers may comprise poly(olefin sulfones), poly(esters), or poly(acetals). In some embodiments, the self-immolative polymers may comprise the following:

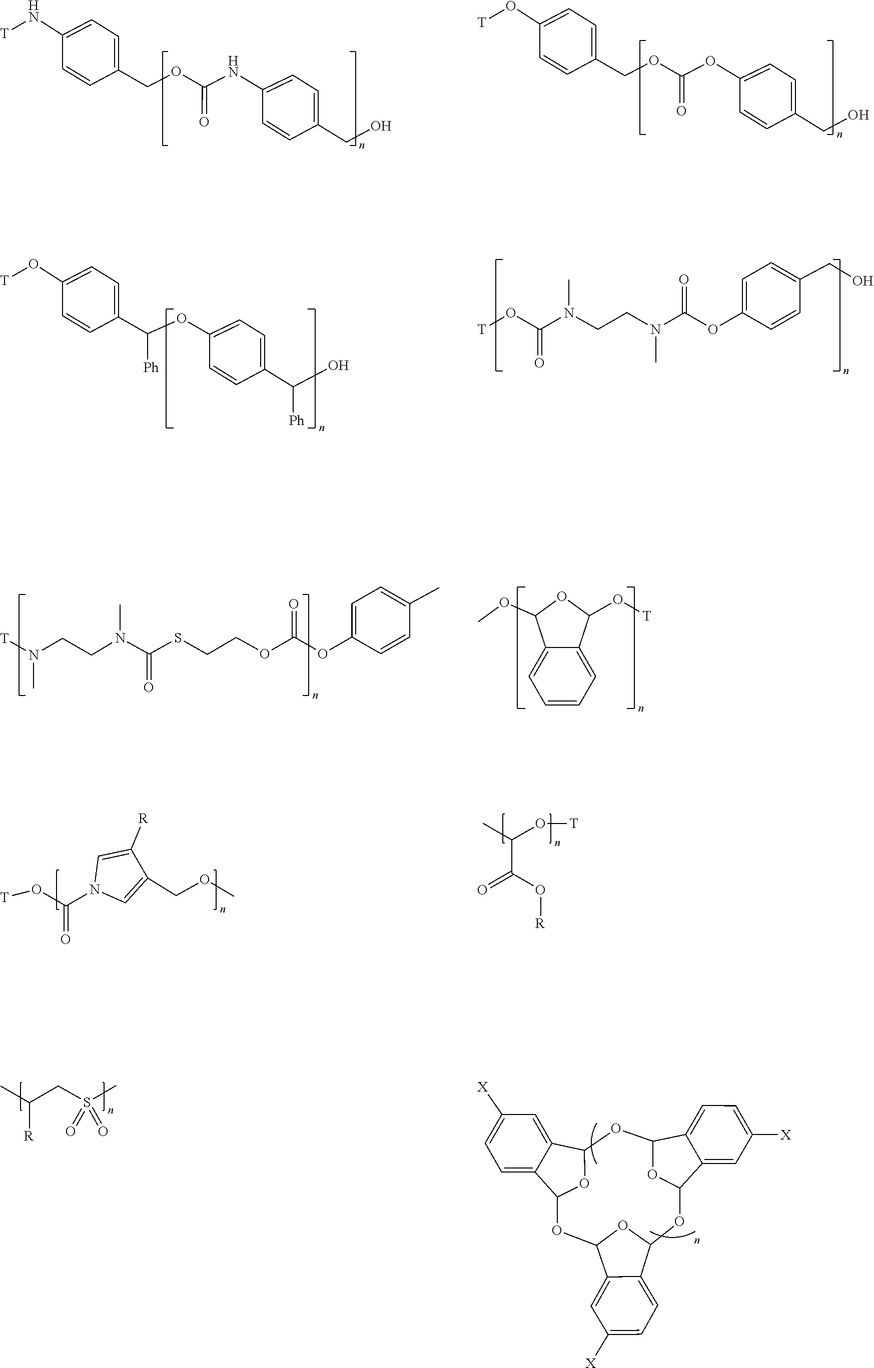

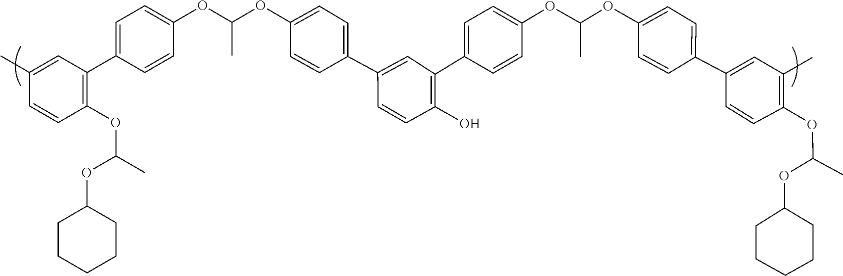

where T may be a trigger group that is stimuli responsive to the solubility shifting agent.

FIGS. 4A-4C illustrate the depolymerization mechanism of self-immolative polymers in response to external stimuli, in accordance with an embodiment. As shown in FIG. 4A, the initial polymer chain 402 maintains structural integrity before activation. In FIG. 4B, an external stimulus 40 may trigger a reaction at an initiation site 406, which begins the depolymerization cascade as indicated by the arrows. FIG. 4C shows the progression of the depolymerization process, where the polymer chain 402 breaks down into individual segments through a domino-like fragmentation reaction.

In various embodiments, the self-immolative polymers may respond to the external stimuli 40 comprising light, acid/base exposure, heat, reduction, oxidation, or fluoride ions. The triggered depolymerization may propagate along the polymer backbone in a cascade reaction. For example, poly(phthalaldehyde) may undergo rapid depolymerization in solid state when triggered. In another embodiment, polyurethane-based self-immolative polymers may decompose through sequential 1,6-elimination and decarboxylation reactions. The depolymerization may convert the solid polymer film into volatile small molecules that can be readily removed from the substrate surface. This controlled breakdown mechanism enables selective removal of polymer material in regions where the trigger stimulus has been applied.

In one or more embodiments, the second resist layer 112 may include a photoacid generator. The photoacid generator may be as previously described with respect to the photoacid generator included in the first patterned resist layer 106.

In one or more embodiments, the second resist layer 112 may include a solvent. The solvent may be as previously described with respect to the solvent included in the first patterned resist layer 106 or the solubility shifting agent. In particular embodiments, the solvent in the second resist is the same as the solvent in the solubility shifting agent.

In some embodiments, the second resist layer 112 may comprise additives having various purposes, depending on the particular chemistry being used. In some embodiments, the second resist layer 112 may comprise a quencher. In various embodiments, the quencher may help control the diffusion of the active material in the solubility shifting agent. The quenchers may comprise the bases previously listed with reference to the solubility shifting agent material.

In some embodiments, the second resist layer 112 may further comprise a PTD or NTD resist. Both PTD and NTD rests may include a polymer and a solvent as described above. In some embodiments, the second resist layer 112 is an NTD resist comprising an acid or acid generator. The acid or acid generator may be as previously described with reference to the solubility shifting agent material.

In FIG. 1F, the solubility shifting agent in the first patterned resist layer 106 may be activated and diffused into the second resist layer 112. In some embodiments, the solubility shifting agent may diffuse into portions of the second resist layer 112 to form solubility shifted regions 114 in the second resist layer 112. In one or more embodiments, activating and diffusing the solubility shifting agent into the second resist layer 112 may be achieved by applying heat (or a bake) to the substrate to activate the solubility shifting agent. The bake may be carried out with a hotplate or oven. The temperature and time of the bake may depend on the identity of the second resist layer 112, and the desired amount of diffusion of the solubility shifting agent into the second resist layer 112. In some embodiments, conditions for the bake may comprise a temperature ranging from 50° C. to 160° C., and a time ranging from about 30 to 90 seconds.

In one or more embodiments, the solubility shifted regions 114 may be present around the edges of the second resist layer 112. The amount of diffusion of the solubility shifting agent may correspond to the thickness of the solubility shifted regions 114. In some embodiments, the solubility shifted regions 114 may extend into the second resist layer 112 such that it has a thickness of about 5 to about 60 nm. In some embodiments, the thickness of the solubility shifted regions 114 may range from a lower limit of one of 5, 10, 15, 20, and 25 nm to an upper limit of one of 40, 45, 50, 55, and 60 nm, where any lower limit may be paired with any mathematically compatible upper limit. The solubility shifted regions 114 may have a different solubility than the region of the second resist that was unexposed to the solubility shifting agent. Subsequent development process of the substrate may enable removing the solubility shifted regions 114.

FIG. 1G illustrates a dry development process utilizing a thermal development process 10 to remove the solubility shifted regions 114. In various embodiments, the thermal development process 10 may convert the solubility shifted regions 114 into volatile compounds that evaporate from the substrate surface.

In one or more embodiments, the thermal development process 10 may comprise heating the substrate to temperatures between 50° C. and 300° C. The thermal development process 10 may be conducted for a duration between 1 and 15 minutes. In an embodiment, the thermal development process 10 may occur on a hotplate under controlled ambient conditions. Alternative heating approaches may include processing in a chamber, an oven, or other thermal processing equipment.

In various embodiments, environment of the thermal development process 10 may be controlled through introduction of specific gases comprising air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, helium, or combinations thereof. The ambient pressure during thermal development may range from atmospheric pressure to vacuum conditions. The controlled ambient conditions and heating parameters enable precise removal of the solubility shifted regions 114 while maintaining pattern fidelity.

The thermal development process 10 may be performed in various types of process chambers operating under atmospheric conditions. In one or more embodiments, these process chambers may comprise wafer cleaning chambers, bake chambers, or treatment chambers. In some embodiments, the thermal development process 10 may utilize existing semiconductor processing equipment such as wafer spin-clean chambers, bevel edge clean chambers, post-application bake chambers, post-exposure bake chambers, batch furnace reactors, buffer modules, development chambers, or hexamethyldisilazane (HMDS) treatment chambers.

In various embodiments, the process chambers for the thermal development process 10 may be integrated within a track system or cluster tool for photoresist processing. This integration enables the dry development process to occur in the same station, module, or chamber as other photoresist processing steps, eliminating the need for separate equipment or additional substrate transfers.

FIGS. 3A and 3B illustrate variations of the dry development process shown in FIG. 1G, in accordance with various embodiments. FIG. 3A shows a gas development process 30 for removing the solubility shifted regions 114 from the substrate. FIG. 3B depicts a light development process 32 for removing these regions.

In various embodiments, the gas development process 30 may comprise exposing the substrate to reactive gases. The reactive gases may comprise air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, or helium. In one or more embodiments, the gas development process 30 may utilize halogen-containing gases comprising compounds containing hydrogen, fluorine, chlorine, bromine, or iodine. In some embodiments, a plasma may be generated from the reactive gases or halogen-containing gases to improve efficiency of the dry development process.

The reactive gases or halogen-containing gases may chemically interact with the solubility shifted regions 114 to form volatile reaction products. In various embodiments, these volatile products may be removed from the substrate through vacuum evacuation, gas purging, or thermal desorption processes. The chemical conversion of solubility shifted regions 114 to volatile species may be enhanced by heating the substrate during gas exposure. In one or more embodiments, the reaction products sublimate or evaporate from the substrate surface, leaving clean openings in the resist pattern.

FIG. 3B illustrates the light development process 32 where light beams may be used to remove the solubility shifted regions 114. In various embodiments, the light beams may comprise infrared radiation, visible light, ultraviolet radiation, or combinations thereof to heat the substrate or initiate photochemical reactions. In an embodiment, the light source may include laser beams, LED arrays, flash lamps, or broad-spectrum light sources. The light development process 32 may utilize focused or patterned light beams to selectively heat and remove the solubility shifted regions 114.

In one or more embodiments, the light development process 32 may employ specific wavelengths or wavelength ranges selected to match absorption characteristics of the solubility shifted regions 114. The light exposure may be continuous or pulsed, and the intensity and duration can be controlled to achieve optimal removal of the modified regions while maintaining pattern fidelity.

In various embodiments, the thermal development process 10, gas development process 30, and light development process 32 may be performed individually or in combinations thereof. For example, the substrate 100 may be simultaneously heated and exposed to reactive gases to enhance removal of solubility shifted regions 114. In another embodiment, light exposure may be combined with reactive gas treatment to initiate photochemical reactions that facilitate material removal. The combination of different development approaches enables optimization of process parameters for specific resist materials and pattern requirements. In one or more embodiments, these processes may be performed sequentially, where one development technique prepares or initiates the removal process that is then completed by another technique.

FIG. 1H illustrates the structure after completion of the dry development process, where openings 117 are formed between the first patterned resist layer 106 and the remaining portions of the second resist layer 112. The remaining portions of the second resist layer 112 may be referred to as a second patterned resist layer 116. The dry development processes described with reference to FIGS. 1G, 3A, and 3B remove the solubility shifted regions 114 without using liquid developers, thereby eliminating capillary forces that typically occur during wet development processes.

In various embodiments, the absence of liquid-induced capillary effects during dry development enables formation of high-fidelity openings 117 with preserved critical dimensions. The elimination of surface tension and capillary forces may prevent pattern collapse or deformation that commonly occurs in conventional wet development processes, particularly when feature dimensions decrease to nanometer scale. This improved pattern fidelity leads to enhanced resolution and reduced defectivity in subsequent pattern transfer steps. In various embodiments, the first and the second patterned resist layers 106 and 116 may be used as a combined etch mask for subsequent processes.

FIG. 1I illustrates an etching process that transfers patterns in the combined etch mask into the layer to-be-etched 104. The etching process may continue until the underlying substrate layer 102 is exposed, creating transferred features that replicate the pattern of the combined etch mask.

In various embodiments, the etching process may comprise dry etching techniques such as reactive ion etching (RIE), inductively coupled plasma (ICP) etching, electron cyclotron resonance (ECR) etching, or combinations thereof. The etching chemistry may be selected based on the composition of the layer to-be-etched 104. In one or more embodiments, the etching process may utilize fluorine-based chemistry for silicon-containing materials, chlorine-based chemistry for metal-containing materials, or oxygen-based chemistry for organic materials.

In an embodiment, the etching process parameters include RF power, bias power, pressure, gas flow rates, and temperature. These parameters may be optimized to achieve high etch selectivity between the layer to-be-etched 104 and the combined etch mask. The process may also employ pulsed plasma, multi-step etching sequences, or passivation steps to control feature profiles and dimensions.

In various embodiments, endpoint detection techniques may monitor the etching process to determine when the underlying substrate layer 102 is exposed. These techniques may include optical emission spectroscopy, interferometry, or mass spectrometry to detect changes in plasma chemistry or surface reflection that indicate completion of the pattern transfer process.

FIGS. 6A and 6B illustrate a process variation of the patterning process described in FIGS. 1A-1I, in accordance with one embodiment.

FIG. 6A shows the substrate 100 after depositing the second resist layer 112 over the first patterned resist layer 106, as described in FIG. 1E. In various embodiments, the first patterned resist layer 106 may comprise solubility shifting agents that diffuse a fixed distance from the coating layer 108 into the first patterned resist layer 106 to form solubility shifted regions 610. Unlike previous embodiments, this process may not involve diffusion of solubility shifting agent from the first patterned resist layer 106 into the second resist layer 112.

In various embodiments, the first patterned resist layer 106 may comprise similar materials as described for the second resist layer 112, including self-immolative polymers, deprotectable resins with acid-labile groups, or other compositions that respond to solubility shifting agents through controlled depolymerization or chemical modification. In various embodiments, the solubility shifted regions 610 may exhibit different chemical properties that make them selectively removable through dry development processes.

FIG. 6B illustrates the substrate 100 after the dry development process has been performed. In various embodiments, the dry development process may employ similar techniques as described above with reference to the thermal development process 10, the gas development process 30, the light development process 32, or combinations thereof. The dry development process may selectively remove solubility shifted regions 610 while leaving the second resist layer 112 intact. This may create openings 617 within the first patterned resist layer 106, transforming it into a modified first patterned resist layer 606.

Following the dry development process, the modified first patterned resist layer 606 and the second resist layer 112 together form a combined etch mask. In various embodiments, this combined etch mask may be used to etch the layer to-be-etched 104 following processes similar to those described with reference to FIG. 1I. The selective removal of only the solubility shifted regions 610 while maintaining the integrity of both resist layers enables formation of complex pattern features with a single lithography step.

In various embodiments, intermediate processing steps may be performed between the primary patterning steps illustrated in FIGS. 1A-1I and 6A-6B. The substrate 100 may be transferred between different process chambers or tools for specific operations. These transfers may occur under controlled environmental conditions to prevent pattern degradation or contamination. In one or more embodiments, cleaning processes may remove residues or particles between steps using techniques such as plasma treatment, UV-ozone exposure, or surface energy modification. Temperature control steps may be implemented to stabilize the substrate 100 before or after thermal processes. In various embodiments, metrology or inspection steps monitor pattern quality, critical dimensions, or overlay alignment. Additional coating or treatment steps may modify surface properties to enhance subsequent processes. In some embodiments, the substrate 100 may also undergo dehydration baking, priming treatments such as hexamethyldisilazane (HMDS) application, or anti-reflection coating processes between the primary patterning steps.

FIGS. 5A-5H illustrate cross-sectional views of process steps for patterning a substrate using photoresist materials with pre-incorporated solubility shifting agents, in accordance with one embodiment. Components and features in FIGS. 5A-5H that share reference numbers with those in FIGS. 1A-1I have corresponding structures and operations as previously described.

FIG. 5A illustrates a substrate 500 comprising a first resist layer 502, the layer to-be-etched 104, and the substrate layer 102. In various embodiments, the first resist layer 502 may comprise similar materials as the first patterned resist layer 106 described above. The first resist layer 502 may comprise both a photoacid generator and a solubility shifting agent pre-mixed within the resist composition. The photoacid generator and the solubility shifting agent may comprise similar materials as described above with reference to FIGS. 1A-1I.

In various embodiments, the first resist layer 502 may undergo selective exposure to actinic radiation 50 through a photomask 520. In various embodiments, the actinic radiation 50 may comprise deep ultraviolet radiation from KrF excimer lasers, ArF excimer lasers, or extreme ultraviolet (EUV) radiation. In various embodiments, the photomask 520 may comprise radiation-stepping regions 524 and radiation-transmitting regions 522. The radiation-transmitting regions 522 allow actinic radiation 50 to reach corresponding portions of the first resist layer 502, while radiation-stepping regions 524 protect underlying portions from exposure.

FIG. 5B illustrates the substrate 500 after exposure to the actinic radiation 50, where exposed portions 503 and unexposed portions 504 are formed in the first resist layer 502 corresponding to the pattern of photomask 520. In one or more embodiments, the actinic radiation 50 may activate the photoacid generator in the exposed portions 503 through the radiation-transmitting regions 522. The activated photoacid generator may produce acid that initiates deprotection reactions in the resist material, changing solubility properties of the exposed portions 503. The unexposed portions 504, protected by radiation-stepping regions 524, maintain their original chemical composition. In various embodiments, the different solubility properties between the exposed portions 503 and the unexposed portions 504 enable subsequent pattern development.

FIG. 5C illustrates the substrate 500 after removal of the exposed portions 503 to form a first patterned resist layer 506 having openings 507. In various embodiments, the exposed portions 503 may be removed through development processes that selectively dissolve regions where deprotection reactions have occurred. The remaining unexposed portions 504 may form the first patterned resist layer 506, also referred to as a first relief pattern.

In one or more embodiments, the development process may utilize an aqueous base developer such as tetramethylammonium hydroxide (TMAH) solution. The deprotected polymer in exposed portions 503 becomes soluble in the aqueous base developer due to the formation of polar functional groups, while the protected polymer in unexposed portions 504 remains insoluble. Alternative developers may include organic solvents, surfactant-containing solutions, or specialized development chemistries matched to the resist composition.

The development process parameters, including developer concentration, development time, and temperature, may be controlled to achieve complete removal of the exposed portions 503 while maintaining dimensional integrity of the first patterned resist layer 506. In various embodiments, the development process may include steps such as puddle development, spray development, or immersion development, followed by deionized water rinsing and drying steps. The resulting first patterned resist layer 506 may serve as a template for subsequent processing steps while retaining the incorporated solubility shifting agent. In various embodiments, the openings 507 may expose a top surface of the layer to-be-etched 104.

FIG. 5D illustrates deposition of a second resist layer 512 over the first patterned resist layer 506. In various embodiments, the second resist layer 512 may fill the openings 507 and cover the first patterned resist layer 506. The second resist layer 512 may comprise similar materials as described above for the second resist layer 112.

After deposition of the second resist layer 512, the solubility shifting agent pre-incorporated within the first patterned resist layer 506 may be activated to diffuse into adjacent portions of the second resist layer 512, as illustrated by the arrows. The activation and diffusion processes may follow similar mechanisms as described with reference to FIG. 1F, creating solubility shifted regions in portions of the second resist layer 512 adjacent to the first patterned resist layer 506.

In various embodiments, where the solubility shifting agent comprises a thermal acid generator (TAG), activation may occur through thermal treatment of the substrate 500. The thermal treatment may include heating the substrate 500 to temperatures sufficient to activate the TAG and initiate diffusion into the second resist layer 512. In one or more embodiments, the thermal treatment parameters, including temperature, duration, and ambient conditions, control the diffusion distance of the solubility shifting agent into the second resist layer 512. The controlled diffusion creates precisely defined regions of modified solubility properties within the second resist layer 512.

FIG. 5E shows the substrate 500 after solubility shifting agent diffusion into the second resist layer 512. The diffusion may form solubility shifted regions 514 in portions of the second resist layer 512. In one or more embodiments, the solubility shifted regions 514 may be present around the edges of the second resist layer 512. The amount of diffusion of the solubility shifting agent may correspond to the thickness of the solubility shifted regions 514. In some embodiments, the solubility shifted regions 514 may extend into the second resist layer 512 such that it has a thickness of about 5 to about 60 nm. In some embodiments, the thickness of the solubility shifted regions 514 may range from a lower limit of one of 5, 10, 15, 20, and 25 nm to an upper limit of one of 40, 45, 50, 55, and 60 nm, where any lower limit may be paired with any mathematically compatible upper limit. The solubility shifted regions 514 may have a different solubility than regions of the second resist layer 512 that are unexposed to the solubility shifting agent. Subsequent development process of the substrate may enable removing the solubility shifted regions 514.

FIG. 5F illustrates a dry development process 52 that removes solubility shifted regions 514 from the second resist layer 512. In various embodiments, the dry development process 52 may employ similar techniques as described above with reference to the thermal development process 10, the gas development process 30, the light development process 32, or combinations thereof. In one or more embodiments, the dry development process 52 may comprise thermal treatment to convert solubility shifted regions 514 into volatile compounds that evaporate from the substrate surface. Alternatively, the process may utilize reactive gases to chemically remove the solubility shifted regions 514, or employ light exposure to initiate photochemical or photothermal removal processes.

FIG. 5G illustrates that the removal of solubility shifted regions 514 through the dry development process 52 may create openings 517 between the first patterned resist layer 506 and remaining portions of the second resist layer 512. The remaining portions of the second resist layer 512 may form a second patterned resist layer 516. The openings 517 may expose the top surface of the layer to-be-etched 104. In various embodiments, the first and the second patterned resist layers 506 and 516 may be used as a combined etch mask for subsequent processes.

FIG. 5H illustrates an etching process that transfers patterns in the combined etch mask into the layer to-be-etched 104. The etching process may continue until the underlying substrate layer 102 is exposed, creating transferred features that replicate the pattern of the combined etch mask. In various embodiments, the etching process in FIG. 5H may employ similar techniques and methods as described above with reference to FIG. 1I.

In various embodiments, intermediate processing steps may be performed between the primary patterning steps illustrated in FIGS. 5A-5H. The substrate 100 may be transferred between different process chambers or tools for specific operations. These transfers may occur under controlled environmental conditions to prevent pattern degradation or contamination. In one or more embodiments, cleaning processes may remove residues or particles between steps using techniques such as plasma treatment, UV-ozone exposure, or surface energy modification. Temperature control steps may be implemented to stabilize the substrate 500 before or after thermal processes. In various embodiments, metrology or inspection steps monitor pattern quality, critical dimensions, or overlay alignment. Additional coating or treatment steps may modify surface properties to enhance subsequent processes. In some embodiments, the substrate 500 may also undergo dehydration baking, priming treatments such as hexamethyldisilazane (HMDS) application, or anti-reflection coating processes between the primary patterning steps.

FIG. 7 illustrates a flow diagram of a method for patterning a substrate, in accordance with an embodiment. The process may begin at step 702 by providing a substrate comprising a first patterned resist layer, similar to the structures described with reference to FIGS. 1A and 5A-5C. In various embodiments, the first patterned resist layer may be formed through photolithographic processes including exposure and development as detailed above.

At step 704, a coating layer comprising solubility shifting agent (SSA) may be applied over the first patterned resist layer. The SSA may diffuse into the first patterned resist layer as illustrated in FIGS. 1B-1C and FIG. 2. In one or more embodiments, the SSA may comprise thermal acid generators or other composition as previously described. The diffusion process may follow surface-limited mechanism as described with reference to FIG. 1C or through-thickness mechanism as described with reference to FIG. 2.

Step 706 involves removing the coating layer and depositing a second resist layer over the first patterned resist layer, corresponding to processes shown in FIGS. 1D-IE. As described above, the second resist layer may comprise self-immolative polymers or other suitable materials detailed in the description with reference to FIG. 1E.

At step 708, the SSA may diffuse from the first patterned resist layer into portions of the second resist layer to form solubility shifted regions, as illustrated in FIGS. 1F and 5E. The diffusion process may be activated through thermal treatment or other methods previously described.

Step 710 comprises performing a dry development process to remove the solubility shifted regions, forming a second patterned resist layer. In various embodiments, this step utilizes thermal development, gas development, or light development processes as detailed in the discussions of FIGS. 1G, 3A, and 3B. The dry development processes may be performed individually or in combinations as previously described.

Finally, at step 712, the substrate may be etched using the first and second patterned resist layers as a combined etch mask, corresponding to processes shown in FIGS. 1I and 5H. The etching process may employ techniques and parameters as detailed above to transfer the pattern into the layer to-be-etched.

FIG. 8 illustrates a flow diagram of an alternative method for patterning a substrate, in accordance with an embodiment. The process begins at step 802 by providing a substrate comprising a first patterned resist layer which contains pre-incorporated solubility shifting agent, corresponding to structures described with reference to FIGS. 5A-5C. In various embodiments, the first patterned resist layer may comprise photoacid generator and SSA within its composition, and is patterned through photolithographic exposure and development processes as detailed above.

At step 804, a second resist layer may be deposited over the first patterned resist layer, as illustrated in FIG. 5D. In various embodiments, the second resist layer may comprise materials previously described with reference to FIG. 1E.

Step 806 involves diffusing the SSA from the first patterned resist layer into the second resist layer to form solubility shifted regions, corresponding to processes shown in FIG. 5E. In one or more embodiments, the SSA may comprise thermal acid generators that are activated through thermal treatment as previously described. The diffusion process creates precisely defined regions of modified solubility within the second resist layer (e.g., the solubility shifted regions).

At step 808, a dry development process may remove the solubility shifted regions to form a second patterned resist layer, as illustrated in FIG. 5F. The dry development may utilize thermal development, gas development, or light development processes as detailed in the discussions of FIGS. 1G, 3A, and 3B. In various embodiments, these development processes may be performed individually or in combinations as previously described.

Finally, at step 810, the substrate may be etched using the first and second patterned resist layers as a combined etch mask, corresponding to processes shown in FIGS. 5G-5H. The etching process may employ techniques and parameters as detailed above to transfer the pattern into the layer to-be-etched, following similar processes as described with reference to FIG. 1I.

FIG. 9 illustrates a flow diagram of a method variation for patterning a substrate, in accordance with an embodiment.

At step 902, a substrate comprising a first patterned resist layer may be provided. In various embodiments, the substrate may be similar to the substrate 100 comprising a first patterned resist layer 106 as described with reference to FIGS. 1A and 6A. The first patterned resist layer may comprise similar materials as described for the second resist layer 112, including self-immolative polymers, deprotectable resins with acid-labile groups, or other compositions that respond to solubility shifting agents through controlled depolymerization or chemical modification. The first patterned resist layer may be formed through photolithographic processes including exposure and development as detailed above.

At step 904, a coating layer may be deposited over the first patterned resist layer, and the solubility shifting agent in the coating layer may diffuse into the first patterned resist layer, forming solubility shifted regions in the first patterned resist layer. This process may correspond to the application of coating layer 108 and formation of solubility shifted regions 610 as described with reference to FIGS. 1B-1C, and FIG. 6A. In various embodiments, the solubility shifting agent may comprise thermal acid generators or other compositions as previously described, and the diffusion process may follow surface-limited or through-thickness mechanisms.

At step 906, the coating layer may be removed and a second resist layer may be deposited over the first patterned resist layer. This step may correspond to processes shown in FIGS. 1D-IE and FIG. 6A.

At step 910, a dry development process may be performed to remove the solubility shifted regions, forming a modified first patterned resist layer. In various embodiments, this step may utilize thermal development, gas development, or light development processes as detailed in the discussions of FIGS. 1G, 3A, 3B, and 6B. The dry development processes may be performed individually or in combinations as previously described. In various embodiments, the dry development process may selectively remove solubility shifted regions 610 to form a modified first patterned resist layer 606 with openings 617 as shown in FIG. 6B.

At step 912, the substrate may be etched using the modified first patterned resist layer and the second resist layer as a combined etch mask. This etching process may correspond to processes shown in FIGS. 1I and 6B. In various embodiments, the etching process may employ techniques and parameters as detailed above to transfer the pattern into the layer to-be-etched 104. The combined etch mask may enable formation of complex pattern features with a single lithography step.

In various embodiments, additional processing steps may be performed between the steps illustrated in FIGS. 7-9. These intermediate steps may include substrate transfers between process chambers under controlled environmental conditions, cleaning processes to remove residues or contaminants, and temperature stabilization steps before or after thermal treatments. In one or more embodiments, metrology steps measure critical dimensions, overlay accuracy, or inspect for defects between primary patterning steps. Surface preparation processes such as dehydration baking, hexamethyldisilazane (HMDS) treatment, or anti-reflection coating application may be performed to optimize subsequent process steps. The substrate may undergo plasma treatment, UV-ozone exposure, or surface energy modification between coating steps to enhance adhesion or wetting properties. In various embodiments, rework processes may be implemented if metrology results indicate pattern defects or dimensional variations outside acceptable ranges. These intermediate steps, while not explicitly shown in the flow diagrams, contribute to process optimization and pattern quality control throughout the complete patterning sequence.

Example embodiments of the invention are described below. Other embodiments can also be understood from the entirety of the specification as well as the claims filed herein.

Example 1. A method for processing a substrate, the method including: providing a substrate including a first patterned resist layer deposited disposed over a layer to-be-etched, where the first patterned resist layer includes solubility shifting agent; depositing disposing a second resist layer over the first patterned resist layer; diffusing the solubility shifting agent into the second resist layer to form solubility shifted regions in the second resist layer; removing the solubility shifted regions using a dry development process to form a second patterned resist layer; and etching the layer to-be-etched using the first and the second patterned resist layers as a combined etch mask.

Example 2. The method of example 1, where diffusing the solubility shifting agent includes applying heat to the substrate to activate the solubility shifting agent.

Example 3. The method of one of examples 1 or 2, where the solubility shifting agent includes an acid generator.

Example 4. The method of one of examples 1 to 3, where the acid generator includes pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, or triphenylsulfonium antiomate.

Example 5. The method of one of examples 1 to 4, where the second resist layer includes self-immolative polymer including poly(olefin sulfones), poly(esters), or poly(acetals).

Example 6. The method of one of examples 1 to 5, where the dry development process includes: heating the substrate to a temperature between 50° C. and 300° C. to thermally remove the solubility shifted regions.

Example 7. The method of one of examples 1 to 6, where the dry development process includes: exposing the substrate to a reactive gas to remove the solubility shifted regions, where the reactive gas includes air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, or helium.

Example 8. The method of one of examples 1 to 7, where the dry development process includes: exposing the substrate to a halogen-containing gas to remove the solubility shifted regions, where the halogen-containing gas includes hydrogen, fluorine, chlorine, bromine, or iodine.

Example 9. A method for patterning a substrate, the method including: providing a substrate including a first patterned resist layer; depositing disposing a coating layer including solubility shifting agent over the first patterned resist layer, where the solubility shifting agent diffuses into the first patterned resist layer; depositing disposing a second resist layer over the first patterned resist layer; activating the solubility shifting agent to diffuse the solubility shifting agent in the first patterned resist layer into portions of the second resist layer to form solubility shifted regions in the second resist layer; and removing the solubility shifted regions using a dry development process to form a second patterned resist layer.

Example 10. The method of example 9, further including: etching the substrate using the first and the second patterned resist layers as a combined etch mask.

Example 11. The method of one of examples 9 or 10, further including: removing the coating layer after depositing disposing the coating layer and before depositing disposing the second resist layer.

Example 12. The method of one of examples 9 to 11, where the activating includes applying heat to the substrate to activate the solubility shifting agent.

Example 13. The method of one of examples 9 to 12, where the dry development process includes: heating the substrate to a temperature between 50° C. and 300° C. to thermally remove the solubility shifted regions.

Example 14. The method of one of examples 9 to 13, where the dry development process includes: exposing the substrate to a reactive gas to remove the solubility shifted regions, where the reactive gas includes air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, or helium.

Example 15. The method of one of examples 9 to 14, where the dry development process includes: exposing the substrate to a halogen-containing gas to remove the solubility shifted regions, where the halogen-containing gas includes hydrogen, fluorine, chlorine, bromine, or iodine.

Example 16. A method of processing a substrate, the method including: providing a substrate including a first resist layer, the first resist layer includes a photoacid generator and a solubility shifting agent; selectively exposing portions of the first resist layer to actinic radiation through a photomask to activate the photoacid generator; developing the first resist layer to remove the exposed portions to form a first relief pattern; depositing a second resist layer to fill openings in the first relief pattern; activating the solubility shifting agent; diffusing the solubility shifting agent into the second resist layer to form solubility shifted regions in the second resist layer; and removing the solubility shifted region using a dry development process.

Example 17. The method of example 16, where exposing the first resist layer to actinic radiation includes: generating an acid from the photoacid generator upon exposure to the actinic radiation; initiating a deprotection reaction by the acid in the exposed portions of the first resist layer; and changing solubility properties of the exposed portions relative to unexposed portions of the first resist layer through the deprotection reaction.

Example 18. The method of one of examples 16 or 17, where the solubility shifting agent is a thermal acid generator, and where activating the solubility shifting agent includes applying heat to the substrate to activate the solubility shifting agent.

Example 19. The method of one of examples 16 to 18, where the dry development process includes: heating the substrate to a temperature between 50° C. and 300° C. to thermally remove the solubility shifted regions.

Example 20. The method of one of examples 16 to 19, where the dry development process includes: exposing the substrate to a gas mixture to remove the solubility shifted regions, where the gas mixture includes air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, helium, or halogen-containing gases including hydrogen, fluorine, chlorine, bromine, or iodine.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-9 may be combined in further embodiments. It is therefore intended that the appended claims encompass any such modifications or embodiments.

What is claimed is:

1. A method for processing a substrate, the method comprising:
providing a substrate comprising a first patterned resist layer deposited over a layer to-be-etched, wherein the first patterned resist layer comprises solubility shifting agent;
depositing a second resist layer over the first patterned resist layer;
diffusing the solubility shifting agent into the second resist layer to form solubility shifted regions in the second resist layer;
removing the solubility shifted regions using a dry development process to form a second patterned resist layer; and
etching the layer to-be-etched using the first and the second patterned resist layers as a combined etch mask.

2. The method of claim 1, wherein diffusing the solubility shifting agent comprises applying heat to the substrate to activate the solubility shifting agent.

3. The method of claim 1, wherein the solubility shifting agent comprises an acid generator.

4. The method of claim 3, wherein the acid generator comprises pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, or triphenylsulfonium antiomate.

5. The method of claim 1, wherein the second resist layer comprises self-immolative polymer comprising poly(olefin sulfones), poly(esters), or poly(acetals).

6. The method of claim 1, wherein the dry development process comprises:
heating the substrate to a temperature between 50° C. and 300° C. to thermally remove the solubility shifted regions.

7. The method of claim 1, wherein the dry development process comprises:
exposing the substrate to a reactive gas to remove the solubility shifted regions, wherein the reactive gas comprises air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, or helium.

8. The method of claim 1, wherein the dry development process comprises:
exposing the substrate to a halogen-containing gas to remove the solubility shifted regions, wherein the halogen-containing gas comprises hydrogen, fluorine, chlorine, bromine, or iodine.

9. A method for patterning a substrate, the method comprising:
providing a substrate comprising a first patterned resist layer;
depositing a coating layer comprising solubility shifting agent over the first patterned resist layer, wherein the solubility shifting agent diffuses into the first patterned resist layer;
depositing a second resist layer over the first patterned resist layer;
activating the solubility shifting agent to diffuse the solubility shifting agent in the first patterned resist layer into portions of the second resist layer to form solubility shifted regions in the second resist layer; and
removing the solubility shifted regions using a dry development process to form a second patterned resist layer.

10. The method of claim 9, further comprising:
etching the substrate using the first and the second patterned resist layers as a combined etch mask.

11. The method of claim 9, further comprising:
removing the coating layer after depositing the coating layer and before depositing the second resist layer.

12. The method of claim 9, wherein the activating comprises applying heat to the substrate to activate the solubility shifting agent.

13. The method of claim 9, wherein the dry development process comprises:
heating the substrate to a temperature between 50° C. and 300° C. to thermally remove the solubility shifted regions.

14. The method of claim 9, wherein the dry development process comprises:
exposing the substrate to a reactive gas to remove the solubility shifted regions, wherein the reactive gas comprises air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, or helium.

15. The method of claim 9, wherein the dry development process comprises:
exposing the substrate to a halogen-containing gas to remove the solubility shifted regions, wherein the halogen-containing gas comprises hydrogen, fluorine, chlorine, bromine, or iodine.

16. A method of processing a substrate, the method comprising:
providing a substrate comprising a first resist layer, the first resist layer comprises a photoacid generator and a solubility shifting agent;
selectively exposing portions of the first resist layer to actinic radiation through a photomask to activate the photoacid generator;
developing the first resist layer to remove the exposed portions to form a first relief pattern;
depositing a second resist layer to fill openings in the first relief pattern;
activating the solubility shifting agent;
diffusing the solubility shifting agent into the second resist layer to form solubility shifted regions in the second resist layer; and
removing the solubility shifted region using a dry development process.

17. The method of claim 16, wherein exposing the first resist layer to actinic radiation comprises:
generating an acid from the photoacid generator upon exposure to the actinic radiation;
initiating a deprotection reaction by the acid in the exposed portions of the first resist layer; and
changing solubility properties of the exposed portions relative to unexposed portions of the first resist layer through the deprotection reaction.

18. The method of claim 16, wherein the solubility shifting agent is a thermal acid generator, and wherein activating the solubility shifting agent comprises applying heat to the substrate to activate the solubility shifting agent.

19. The method of claim 16, wherein the dry development process comprises:
heating the substrate to a temperature between 50° C. and 300° C. to thermally remove the solubility shifted regions.

20. The method of claim 16, wherein the dry development process comprises:
exposing the substrate to a gas mixture to remove the solubility shifted regions, wherein the gas mixture comprises air, water vapor, hydrogen peroxide vapor, carbon dioxide, carbon monoxide, oxygen, ozone, methane, methanol, nitrogen, hydrogen, ammonia, nitrous oxide, nitric oxide, alcohols, acetylacetone, formic acid, argon, helium, or halogen-containing gases comprising hydrogen, fluorine, chlorine, bromine, or iodine.
